(19) United States
(12) Patent Application Publication
(10) Pub. No.: US 2025/0301627 A1
(43) Pub. Date: Sep. 25, 2025

(54) SEMICONDUCTOR DEVICE INCLUDING A VERTICAL CHANNEL

(71) Applicant: SAMSUNG ELECTRONICS CO., LTD., Suwon-si (KR)

(72) Inventors: Jae Won Na, Suwon-si (KR); Junhwa Song, Suwon-si (KR); Heonjun Ha, Suwon-si (KR)

(73) Assignee: SAMSUNG ELECTRONICS CO., LTD., Suwon-si (KR)

(21) Appl. No.: 19/071,322

(22) Filed: Mar. 5, 2025

(30) Foreign Application Priority Data
Mar. 25, 2024 (KR) 10-2024-0040137

(51) Int. Cl. H10B 12/00; H10D 30/63; H10D 64/27

(52) U.S. Cl. CPC H10B 12/315; H10B 12/482; H10B 12/488; H10D 30/63; H10D 64/514; H10D 64/518; H10B 12/05

(57) ABSTRACT

Provided is a semiconductor device and method of manufacturing same, the semiconductor device including: a bit line on a substrate, the bit line extending in a first direction substantially parallel to an upper surface of the substrate; a mold on the bit line, the mold including a porous insulating material; a channel on a sidewall of the mold, wherein the channel is connected to the bit line; an interface pattern between and contacting the channel and the mold; a gate insulation pattern on a sidewall of the channel; a gate electrode on a sidewall of the gate insulation pattern; and a capacitor on and connected to the channel.

### CROSS-REFERENCE TO RELATED APPLICATION

This application claims priority to Korean Patent Application No. 10-2024-0040137 filed on Mar. 25, 2024 in the Korean Intellectual Property Office, the disclosure of which is hereby incorporated by reference in its entirety.

### BACKGROUND

The present disclosure relates to a semiconductor device. More particularly, the present disclosure relates to a memory device including a vertical channel.

Memory devices including a vertical channel transistor have been developed in order to increase the integration degree of a semiconductor device. The vertical channel transistor includes a channel containing an oxide semiconductor material, and when the semiconductor device is manufactured, the channel may be damaged.

### SUMMARY

Provided is a semiconductor device having improved electrical characteristics.

According to an aspect of the disclosure, a semiconductor device includes: a bit line on a substrate, the bit line extending in a first direction substantially parallel to an upper surface of the substrate; a mold on the bit line, the mold including a porous insulating material; a channel on a sidewall of the mold, wherein the channel is connected to the bit line; an interface pattern between and contacting the channel and the mold; a gate insulation pattern on a sidewall of the channel; a gate electrode on a sidewall of the gate insulation pattern; and a capacitor on and connected to the channel.

According to an aspect of the disclosure, a semiconductor device includes: a bit line on a substrate, the bit line extending in a first direction substantially parallel to an upper surface of the substrate; a mold on the bit line, the mold including a porous insulating material; interface patterns on opposite sidewalls of the mold, respectively,, the interface patterns including silicon oxide; a channel on a sidewall of each of the interface patterns, the channel being connected to the bit line; a gate insulation pattern on a sidewall of the channel; a gate electrode on a sidewall of the gate insulation pattern; and a capacitor on and connected to the channel.

According to an aspect of the disclosure, a semiconductor device includes: bit lines on a substrate, each of the bit lines extending in a first direction substantially parallel to an upper surface of the substrate, wherein the bit lines are spaced apart from each other in a second direction substantially parallel to the upper surface of the substrate and crossing the first direction; bit line shields between the bit lines and extending in the first direction; molds spaced apart from each other in the first direction on each of the bit lines, wherein the molds include a porous insulating material; channels each connected to a corresponding one of the bit lines, wherein each of the channels is between molds that neighbor one another in the first direction; an interface pattern between and contacting each of the channels and one of the molds adjacent to each of the channels; a gate insulation pattern on a sidewall of each of the channels; a gate electrode on a sidewall of the gate insulation pattern; landing pads on the channels, respectively; and capacitors on and connected to the channels, respectively.

### BRIEF DESCRIPTION OF DRAWINGS

The above and other aspects and features of certain embodiments of the present disclosure will be more apparent from the following description taken in conjunction with the accompanying drawings, in which:

FIG. 1 is a perspective view illustrating a semiconductor device in accordance with one or more embodiments;

FIG. 2 is a horizontal cross-sectional view illustrating a semiconductor device in accordance with one or more embodiments;

FIG. 3 is a vertical cross-sectional view taken along line A-A′ of FIG. 2;

FIG. 4 is a vertical cross-sectional view taken along line B-B′ of FIG. 2; and

FIGS. 5, 9, 13, 16, 20, 24, 28, 32, 36, 40, 44, 48, 52, 56, 59, 63 and 67 are the perspective views, FIGS. 6, 10 and 17 are the plan views illustrating a method of manufacturing a semiconductor device in accordance with example embodiments;

FIGS. 21, 25, 29, 33, 37, 41, 45, 49, 53, 60 and 64 are the horizontal cross-sectional views illustrating a method of manufacturing a semiconductor device in accordance with example embodiments;

FIGS. 7, 11, 14, 18, 22, 26, 30, 34, 38, 42, 46, 50, 54, 57, 61, 65 and 68 are cross-sectional views taken along lines A-A′ of corresponding plan views or horizontal cross-sectional views, respectively; and

FIGS. 8, 12, 15, 19, 23, 27, 31, 35, 39, 43, 47, 51, 55, 58, 62, 66 and 69 are cross-sectional views taken along lines B-B′ of corresponding plan views or horizontal cross-sectional views, respectively.

### DETAILED DESCRIPTION

The above and other aspects and features of the semiconductor devices, and the methods of manufacturing the same, in accordance with one or more example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Hereinafter, two directions among horizontal directions that are substantially parallel to an upper surface of a substrate, which may intersect each other, may be referred as first and second directions D1 and D2, respectively, and a direction substantially perpendicular to the upper surface of the substrate may be referred to as a third direction D3. In example embodiments, the first and second directions D1 and D2 may be substantially perpendicular to each other. Each of the first to third directions D1, D2 and D3 may include not only a direction shown in the drawing but also a direction that is inverse to the shown direction. Herein, the terms “substantially the same” and “substantially parallel” shall be understood to mean within a 5% margin of “the same” and “parallel,” respectively.

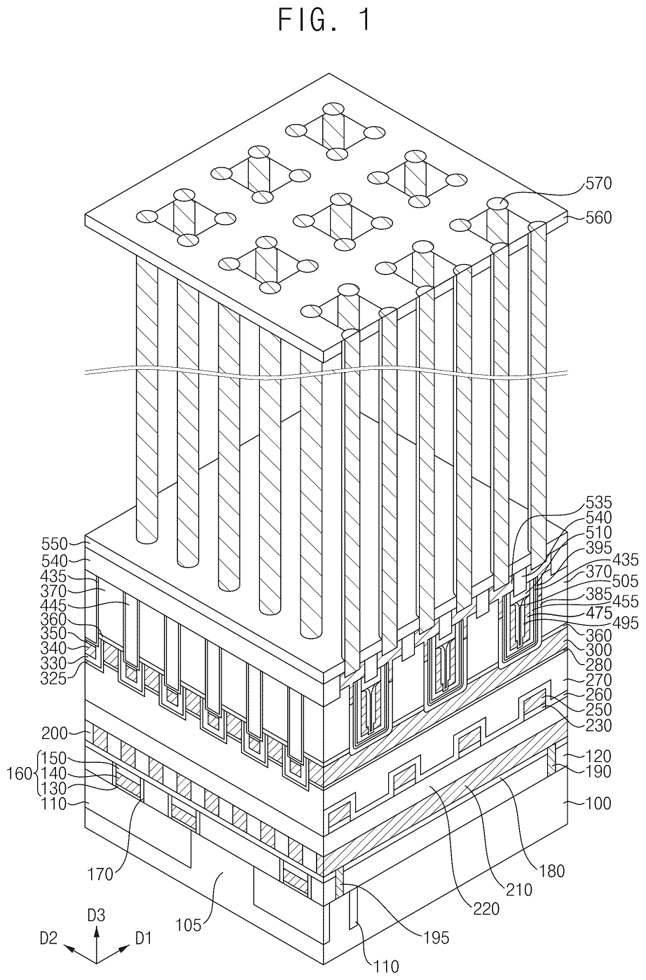

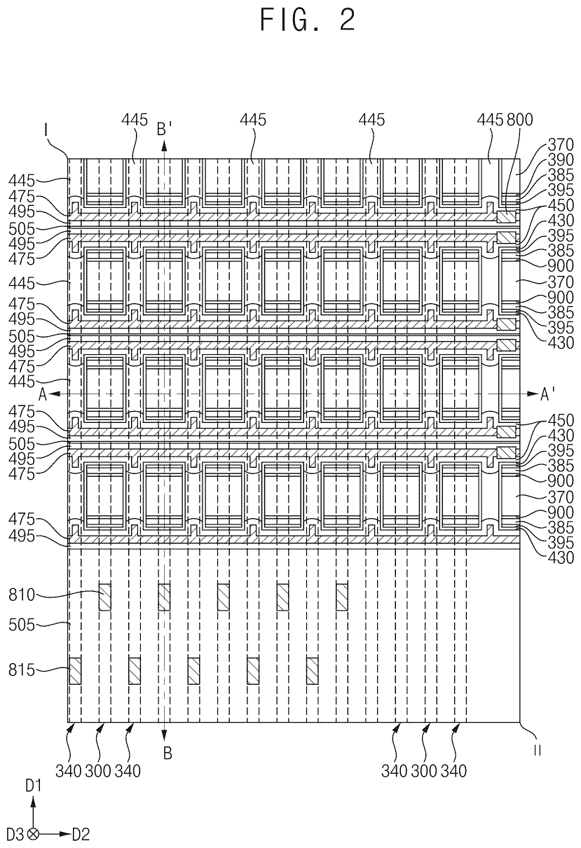

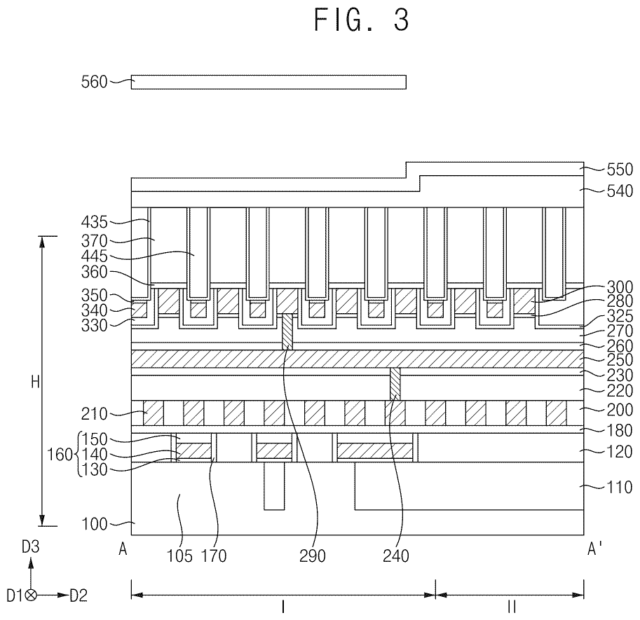

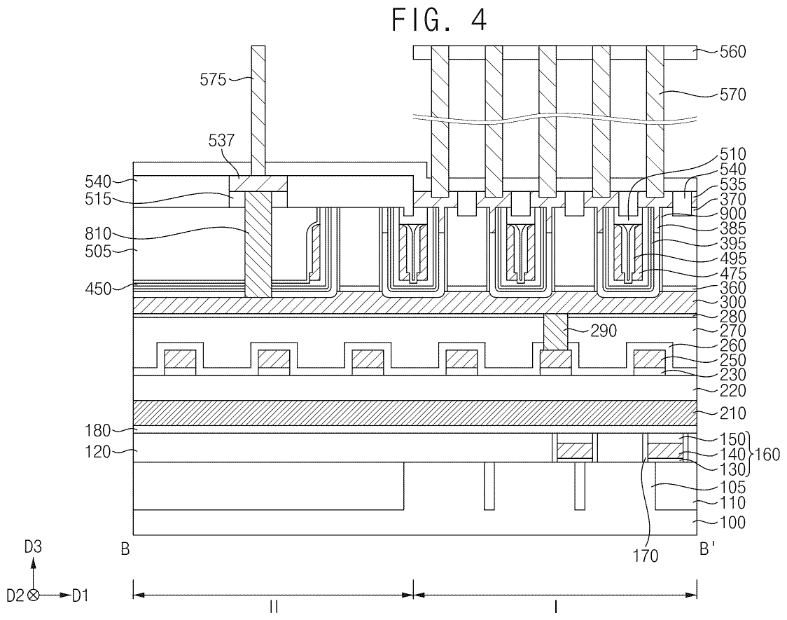

FIGS. 1 to 4 are, respectively, a perspective view, a horizontal cross-sectional view, and two vertical cross-sectional views illustrating a semiconductor device in accordance with one or more example embodiments. Specifically, FIG. 1 is the perspective view, FIG. 2 is the horizontal cross-sectional view, FIG. 3 is a cross-sectional view taken along line A-A′ of FIG. 2, and FIG. 4 is a cross-sectional view taken along line B-B′ of FIG. 2. FIG. 1 shows a first region of the semiconductor device, and FIG. 2 is a horizontal cross-sectional view at a height H of FIGS. 3 and 4.

Referring to FIGS. 1 through 4, the semiconductor device may include a second gate electrode 475, a second gate insulation pattern 455, a channel 385, first, second and fourth capping patterns 395, 435 and 510, an interface pattern 900, first and second landing pads 535 and 537 and a capacitor 570 on a substrate 100.

The semiconductor device may further include an isolation layer 110, a first gate structure 160, a gate spacer 170, a first contact plug 190, a second contact plug, third to eighth contact plugs 240, 290, 800, 810, 815 and 575, first to fourth wirings 210, 250, 300 and 340, a first insulation pattern 230, a second insulation layer 260, third to eighth insulation patterns 280, 310, 325, 330, 350 and 360, a ninth insulation pattern, a first mold 370, first to fifth insulating interlayers 120, 180, 200, 220 and 270, sixth to eighth insulating interlayer patterns 445, 505 and 540, first to second etch stop patterns 495 and 515, a third etch stop layer 550 and a support layer 560.

The substrate 100 may include first and second regions I and II. The first region I may be a cell region on which memory cells are formed, and the second region II may be a peripheral circuit region on which peripheral circuit patterns for applying electrical signals to the memory cells are formed.

The substrate 100 may include silicon, germanium, silicon-germanium, or a III-V group compound semiconductor, e.g., GaP, GaAs, GaSb, etc. In one or more example embodiments, the substrate 100 may be a silicon-on-insulator (SOI) substrate or a germanium-on-insulator (GOI) substrate.

The isolation layer 110 may be disposed on the substrate 100, and an active region 105 may be defined by the isolation layer 110. The isolation layer 110 may include an oxide, e.g., silicon oxide.

The first gate structure 160 may be disposed on the substrate 100, and may include a first gate insulation pattern 130, a first gate electrode 140 and a gate mask 150 sequentially stacked in the third direction D3, and the gate spacer 170 may be disposed on a sidewall of the first gate structure 160. A plurality of first gate structures 160 may be spaced apart from each other in each of the first and second directions D1 and D2. Each of the first gate structures 160 together with source/drain regions at upper portions of the active region 105 may form a transistor. In an example embodiment, the transistor may be a part of a sense amplifier (S/A).

The first gate insulation pattern 130 may include an oxide, e.g., silicon oxide, the first gate electrode 140 may include a conductive material, e.g., a metal, a metal nitride, a metal silicide, doped polysilicon, etc., and each of the gate mask 150 and the gate spacer 170 may include an insulating nitride, e.g., silicon nitride.

The first insulating interlayer 120 may be disposed on the active region 105 and the isolation layer 110, and may also be disposed on a sidewall of gate spacer 170 on the sidewall of the first gate structure 160.

The second insulating interlayer 180 may be disposed on the first insulating interlayer 120, the first gate structure 160 and the gate spacer 170, the first contact plug 190 may extend through the first and second insulating interlayers 120 and 180 to contact an upper surface of the active region 105, e.g., the source/drain region, and the second contact plug 195 may extend through the second insulating interlayer 180 and the gate mask 150 to contact an upper surface of the first gate electrode 140.

The third insulating interlayer 200 may be disposed on the second insulating interlayer 180 and the first and second contact plugs 190 and 195, and the first wiring 210 may extend through the third insulating interlayer 200. In one or more example embodiments, the first wiring 210 may extend in the first direction D1, and a plurality of first wirings 210 may be spaced apart from each other in the second direction D2. Each of the first wirings 210 may contact an upper surface of a corresponding one of the first and second contact plugs 190 and 195.

The fourth insulating interlayer 220 may be disposed on the third insulating interlayer 200 and the first wiring 210, and the first insulation pattern 230 and the second wiring 250 may be sequentially stacked on the fourth insulating interlayer 220. In one or more example embodiments, each of the first insulation pattern 230 and the second wiring 250 may extend in the second direction D2. A plurality of first insulation patterns 230 may be spaced apart from each other in the first direction D1, and a plurality of second wirings 250 may be spaced apart from each other in the first direction D1.

The third contact plug 240 may extend through the first insulation pattern 230 and the fourth insulating interlayer 220, and may contact an upper surface of a corresponding one of the first wirings 210 and a lower surface of a corresponding one of the second wirings 250.

The second insulation layer 260 may be disposed on the fourth insulating interlayer 220, and may also be disposed on a sidewall and an upper surface of the second wiring 250 and a sidewall of the first insulation pattern 230.

The fifth insulating interlayer 270 may be disposed on the second insulation layer 260, and may fill a space between neighboring ones of the second wirings 250 in the first direction D1.

The third insulation pattern 280 and the third wiring 300 may be sequentially stacked on the fifth insulating interlayer 270. In one or more example embodiments, each of the third insulation pattern 280 and the third wiring 300 may extend in the first direction D1. A plurality of third insulation patterns 280 may be spaced apart from each other in the second direction D2, and a plurality of third wirings 300 may be spaced apart from each other in the second direction D2. In one or more example embodiments, each of the third wirings 300 may serve as a bit line of the semiconductor device.

The fourth contact plug 290 may extend through the third insulation pattern 280, and upper portion of the fifth insulating interlayer 270 and the second insulation layer 260, and may contact a lower surface of a corresponding one of the third wirings 300 and an upper surface of a corresponding one of the second wirings 250.

The fifth insulation pattern 325 may extend in the first direction D1 between neighboring ones of the third wirings 300 in the second direction D2 and between neighboring ones of the third insulation patterns 280 in the second direction D2. The fifth insulation pattern 325 may contact sidewalls of the third wirings 300 and the third insulation patterns 280, and further contact an upper surface of the fifth insulating interlayer 270. In one or more example embodiments, the fifth insulation pattern 325 may extend through an upper portion of the fifth insulating interlayer 270, and thus a lower surface of the fifth insulation pattern 325 may be lower than a lower surface of the third insulation pattern 280. In one or more example embodiments, a cross-sectional view of the fifth insulation pattern 325 in the second direction D2 may have a shape of a cup (e.g., a curved or recessed shape).

The sixth insulation pattern 330 may be disposed on the fifth insulation pattern 325 such that the fifth insulation pattern is disposed on a sidewall and a lower surface of the sixth insulation pattern 330. A cross-sectional view in the second direction D2 of the sixth insulation pattern 330 may have a shape of a cup.

The fourth wiring 340 may be disposed on the sixth insulation pattern 330 such that the sixth insulation pattern 330 is disposed on a sidewall and a lower surface of the fourth wiring 340. The seventh insulation pattern 350 may be disposed on the fourth wiring 340 such that the sixth insulation pattern 330 is disposed on a sidewall of the seventh insulation pattern 350. In one or more example embodiments, each of the fourth wiring 340 and the seventh insulation pattern 350 may extend in the first direction D1. A plurality of fourth wirings 340 may be spaced apart from each other in the second direction D2, and a plurality of seventh insulation patterns 350 may be spaced apart from each other in the second direction D2.

In one or more example embodiments, the fourth wiring 340 may be disposed between the third wirings 300 serving as the bit lines, and may serve as a bit line shield.

The eighth insulation pattern 360 and the first mold 370 may be sequentially stacked on the third wiring 300, the fifth insulation pattern 325 and the sixth insulation pattern 330. A plurality of eighth insulation patterns 360 may be spaced apart from each other in each of the first and second directions D1 and D2, and a plurality of first molds 370 may be spaced apart from each other in each of the first and second directions D1 and D2.

In one or more example embodiments, the first mold 370 may include a low density material such as a porous insulating material, e.g., silicon oxide doped with carbon (SiOCH) (which may also be referred to as organic silicate glass) or silicon carbonitride (SiCN).

The sixth insulating interlayer pattern 445 may be disposed on the seventh insulation pattern 350, and may extend in the first direction D1. A plurality of sixth insulation patterns 445 may be spaced apart from each other in the second direction D2 between neighboring ones of the first molds 370 in the second direction D2. The second capping pattern 435 may be disposed on a sidewall in the second direction D2 and a lower surface of the sixth insulating interlayer pattern 445.

The interface pattern 900 may be disposed on each of opposite sidewalls in the first direction D1 of the first mold 370 and the eighth insulation pattern 360. In one or more example embodiments, the interface pattern 900 may include an oxide, e.g., silicon oxide.

The channel 385 may be disposed between neighboring ones of the first molds 370 in the first direction D1 on the third wiring 300 extending in the first direction D1, and a plurality of channels 385 may be spaced apart from each other in the first direction D1. The first capping pattern 395 may be disposed on a sidewall of the channel 385 that is opposite to the first mold 370 and an upper surface of a portion of the channel 385 on the third wiring 300.

In one or more example embodiments, the interface pattern 900 may be disposed between the channel 385, and the first mold 370 and the eighth insulation pattern 360, and thus may enhance an interface characteristic between the first mold 370 including a porous material and the channel 385.

In one or more example embodiments, a cross-section in the first direction D1 of each of the channel 385 and the first capping pattern 395 may have a shape of a cup on the first region I of the substrate 100. The channel 385 and the first capping pattern 395 may also be formed on a portion of the second region II of the substrate 100.

In one or more example embodiments, the channel 385 may include an oxide semiconductor material. The oxide semiconductor material may include at least one of zinc tin oxide (ZTO), indium zinc oxide (IZO), zinc oxide (ZnOₓ), indium gallium zinc oxide (IGZO), indium gallium silicon oxide (IGSO), Indium oxide (InOₓ, In₂O₃). tin oxide (SnO₂), titanium oxide (TiOₓ), zinc oxide nitride (ZnₓOyN_{z}), magnesium zincoxide (MgₓZn_{y}O_{z}), indium zinc oxide (InₓZn_{y}Oₐ), indium gallium zinc oxide (InₓGa_{y}Zn_{z}O_{z}), zirconium indium zinc oxide (ZrₓIn_{y}Zn_{z}Oₐ), hafnium indium zinc oxide (HfₓIn_{y}Zn_{z}Oₐ), tin indium zinc oxide (SnₓIn_{y}Zn_{z}Oₐ) , aluminum tin indium zinc oxide (AlₓSn_{y}In_{z}ZnₐO_{d}), silicon indiumzinc oxide (SiₓIn_{y}Zn_{z}Oₐ), zinc tin oxide (ZnₓSn_{y}O_{z}), aluminum zinc tin oxide (AlₓZn_{y}Sn_{z}Oₐ), gallium zinc tin oxide (GaₓZn_{y}Sn_{z}Oₐ), zirconium zinc tin oxide (ZrₓZn_{y}Sn_{z}Oₐ) and indium gallium silicon oxide (InGaSiO).

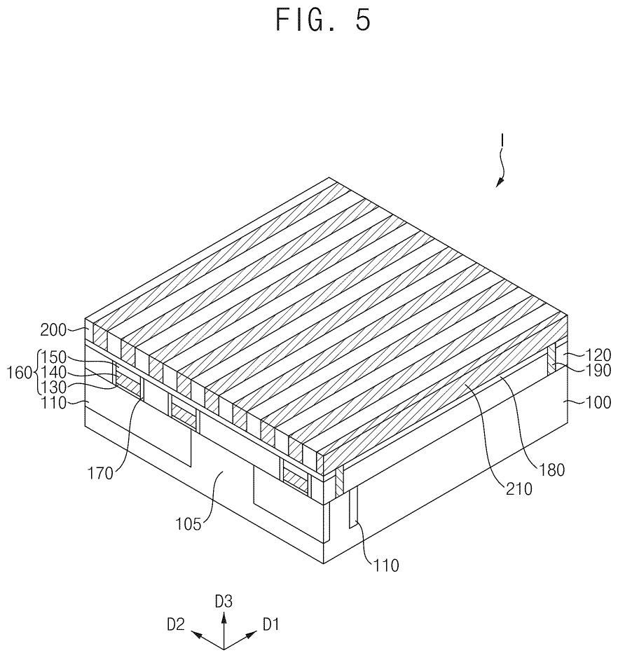

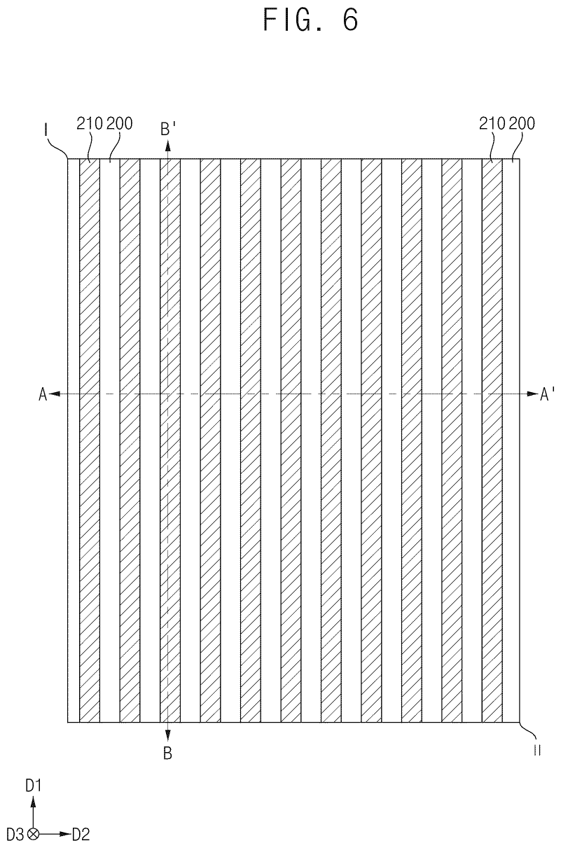

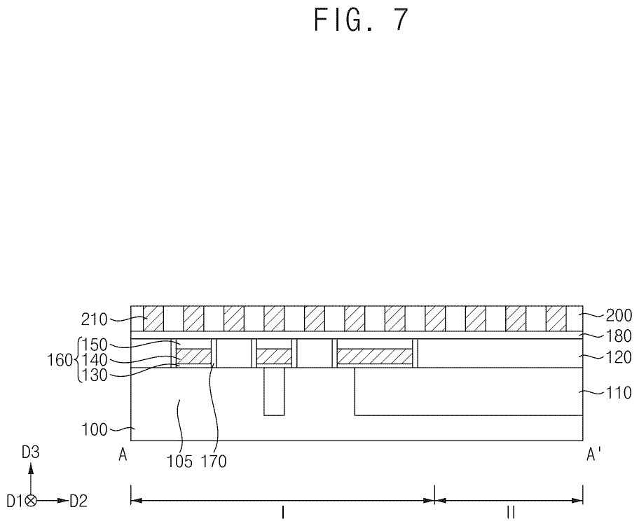

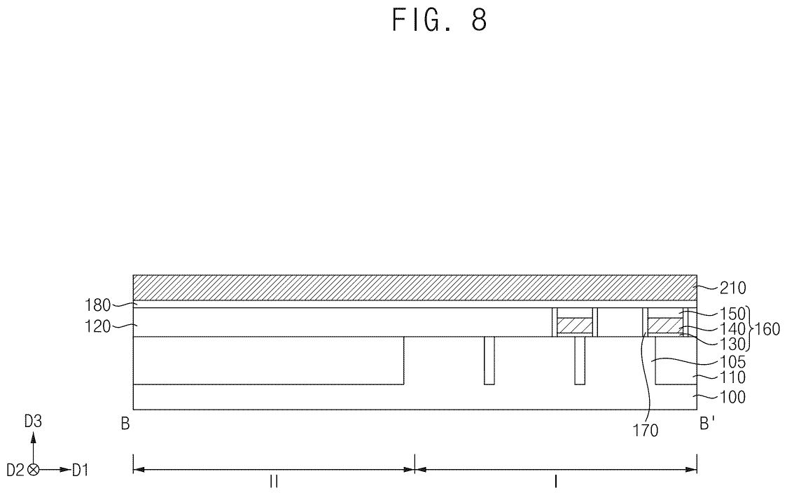

As illustrated below with reference to FIGS. 5 through 69, a small amount of oxygen vacancies may remain in the channel 385.

The second capping pattern 435 may be disposed on the first capping pattern

395. In one or more example embodiments, the second capping pattern 435 may be disposed on opposite sidewalls in the second direction D2 of the first mold 370, opposite sidewalls in the second direction D2 of the channel 385 on each of opposite sidewalls in the first direction D1 of the first mold 370, and a sidewall in the first direction D1 of the first capping pattern 395 on a sidewall in the first direction D1 of the channel 385.

Each of the first and second capping patterns 395 and 435 may include an insulating material, e.g., silicon nitride, silicon oxide, silicon oxycarbide, silicon oxycarbonitride, aluminum oxide, etc. In one or more example embodiments, the first and second capping patterns 395 and 435 may include substantially the same material, and in some cases, may be merged with each other.

The second gate insulation pattern 455 may extend in the second direction D2 on the second capping pattern 435 and the sixth insulating interlayer pattern 445, and a plurality of second gate insulation patterns 455 may be spaced apart from each other in the first direction D1. In one or more example embodiments, a cross-section in the first direction D1 of the second gate insulation pattern 455 may have a shape of a cup.

In one or more example embodiments, in a plan view, a first sidewall of the second gate insulation pattern 455 facing the sixth insulating interlayer pattern 445 in the first direction D1 may have a convex shape toward the sixth insulating interlayer pattern 445, and a groove may be formed on a second sidewall of the second gate insulation pattern 455 that is opposite to the first sidewall thereof.

The second gate insulation pattern 455 may include an oxide, e.g., silicon oxide.

The second gate electrode 475 may be disposed on an inner sidewall of the second gate insulation pattern 455, and may extend in the second direction D2. A plurality of second gate electrodes 475 may be spaced apart from each other in the first direction D1. The second gate electrodes 475 may be disposed on inner sidewalls, respectively, opposite to each other, and may face each other in the first direction D1. The ninth insulation pattern may be disposed at, and contact each of ends in the second direction D2 of, each of the second gate electrodes 475 on the second region II of the substrate 100, and may separate ones of the second gate electrodes 475 neighboring in the first direction D1 from each other.

The second gate electrode 475 and the second gate insulation pattern 455 may collectively form a second gate structure. In one or more example embodiments, each of the second gate electrodes 475 may serve as a word line of the semiconductor device.

The first etch stop pattern 495 may be disposed between neighboring ones of the second gate electrodes 475 in the first direction D1, and may extend in the second direction D1. A lower surface of the etch stop pattern 495 may contact an upper surface of the second gate insulation pattern 455. The etch stop pattern 495 may include an insulating nitride, e.g., silicon nitride.

The seventh insulating interlayer pattern 505 may be disposed on the first etch stop pattern 495 on the first and second regions I and II of the substrate 100, and may extend in the second direction D2 on the first region I of the substrate 100.

In one or more example embodiments, uppermost surfaces of the first etch stop pattern 495 and the second gate electrode 475 may be lower than an uppermost surface of the second gate insulation pattern 455.

The fourth capping pattern 510 may be disposed on the first etch stop pattern 495, the second gate electrode 475 and the second gate insulation pattern 455, and may extend in the second direction D2 on the first region I of the substrate 100.

The second etch stop pattern 515 may be disposed on the seventh insulating interlayer pattern 505, the first mold 370, the first etch stop pattern 495, the first and second capping patterns 395 and 435 and the second gate insulation pattern 455 on the second region II of the substrate 100.

The fifth to seventh contact plugs 800, 810 and 815 may be disposed on the second region II of the substrate 100, and may contact the second gate electrode 475, the third wiring 300 and the fourth wiring 340, respectively. The fifth contact plug 800 may extend through the fourth capping pattern 510 and the first etch stop pattern 495, each of the sixth and seventh contact plugs 810 and 815 may extend through the second etch stop pattern 515, the seventh insulating interlayer pattern 505, the first etch stop pattern 495, the second gate insulation pattern 455, the first and second capping patterns 395 and 435 and the channel 385.

The first landing pad 535 may include a lower portion contacting an upper surface of the channel 385 and an upper portion on the lower portion. A plurality of first landing pads 535 may be spaced apart from each other in each of the first and second directions D1 and D2 on the first region I of the substrate 100. The first landing pad 535 may have a shape of, e.g., a circle, an ellipse, a polygon, a polygon with rounded corners, etc., in a plan view.

In one or more example embodiments, a first sidewall in the first direction D1 of the lower portion of the first landing pad 535 may contact the interface pattern 900, and a second sidewall in the first direction D1 of the lower portion of the first landing pad 535 may contact the first capping pattern 395.

In one or more example embodiments, a lower surface of the first landing pad 535 and an uppermost surface of the channel 385 may be lower than uppermost surfaces of the first and second capping patterns 395 and 435 and the second gate insulation pattern 455. In one or more example embodiments, the lower surface of the first landing pad 535 may be lower than the uppermost surfaces of the seventh insulating interlayer pattern 505, the first etch stop pattern 495 and the second gate electrode 475, however the disclosure is not limited thereto.

A plurality of second landing pads 537 may be spaced apart from each other in each of the first and second directions D1 and D2 on the second region II of the substrate 100. Each of the second landing pads 537 may be disposed on a corresponding one of the fifth to seventh contact plugs 800, 810 and 815.

The eighth insulating interlayer pattern 540 may be disposed on the first mold 370, the sixth insulating interlayer pattern 445, the second and fourth capping patterns 435 and 510 and the second gate insulation pattern 455 on the first region I of the substrate 100, and may also be disposed on sidewalls of the first landing pads 535. A lower surface of the eighth insulating interlayer pattern 540 may be lower than the lower surface of the first landing pad 535. In one or more example embodiments, the lower surface of the eighth insulating interlayer pattern 540 may be lower than the uppermost surface of the second gate insulation pattern 455 and higher than a lower surface of the fourth capping pattern 510.

The third etch stop layer 550 may be disposed on the eighth insulating interlayer pattern 540 and the first and second landing pads 535 and 537. The support layer 560 may be disposed on the third etch stop layer 550 on the first region I of the substrate 100, and may be spaced apart from the third etch stop layer 550 in the third direction D3. Each of the third etch stop layer 550 and the support layer 560 may include an insulating nitride, e.g., silicon nitride.

The capacitor 570 may be disposed on the first landing pad 535, and at least a portion of a lower end and an upper end of the capacitor 570 may be covered and supported by the third etch stop layer 550 and the support layer 560. The capacitor 570 may include a lower electrode, a dielectric layer and an upper electrode, and a plurality of capacitors 570 may be disposed in each of the first and second directions D1 and D2. Each of the lower and upper electrodes may include a conductive material, and the dielectric layer may include a metal oxide having a high dielectric constant, e.g., hafnium oxide, zirconium oxide, etc. The capacitor 570 may have a shape of, e.g., a circle, an ellipse, a polygon, a polygon with rounded corners, etc., in a plan view.

The eighth contact plug 575 may extend through the third etch stop layer 550, and may contact a corresponding one of the second landing pads 537.

Each of the second gate electrode 475, the first contact plug 190, the second contact plug 195, the third to eighth contact plugs 240, 290, 800, 810, 815 and 575, the first to fourth wirings 210, 250, 300 and 340 and the first and second landing pads 535 and 537 may include a conductive material, e.g., a metal, a metal nitride, a metal silicide, etc.

Each of the first, third, fifth and eighth insulation patterns 230, 280, 325 and 360, the second insulation layer 260, the second and third insulating interlayers 180 and 200, the fourth capping pattern 510 and the eighth insulating interlayer pattern 540 may include an insulating nitride, e.g., silicon nitride, and each of the first, fourth and fifth insulating interlayers 120, 220 and 270, the sixth and seventh insulation patterns 330 and 350, the first mold 370 and the sixth to eighth insulating interlayer patterns 445, 505 and 540 may include an oxide, e.g., silicon oxide.

In the semiconductor device, the channel 385 including an oxide

semiconductor material, e.g., IGZO, may include a small amount of oxygen vacancies therein, and thus an on-off characteristic of the semiconductor device including the channel 385 may be enhanced. The interface pattern 900 including an oxide, e.g., silicon oxide, may be disposed between the first mold and the channel 385 in the form of a low density material such as a porous material, so that the interface characteristic between the first mold 370 and the channel 385 may be enhanced.

FIGS. 5 through 69 are perspective views, plan views, horizontal cross-sectional views and vertical cross-sectional views illustrating a method of manufacturing a semiconductor device in accordance with one or more example embodiments.

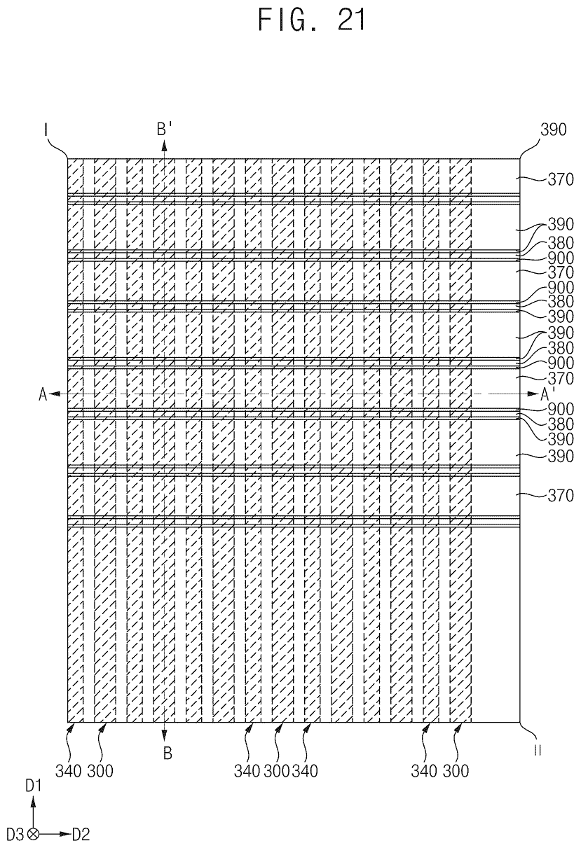

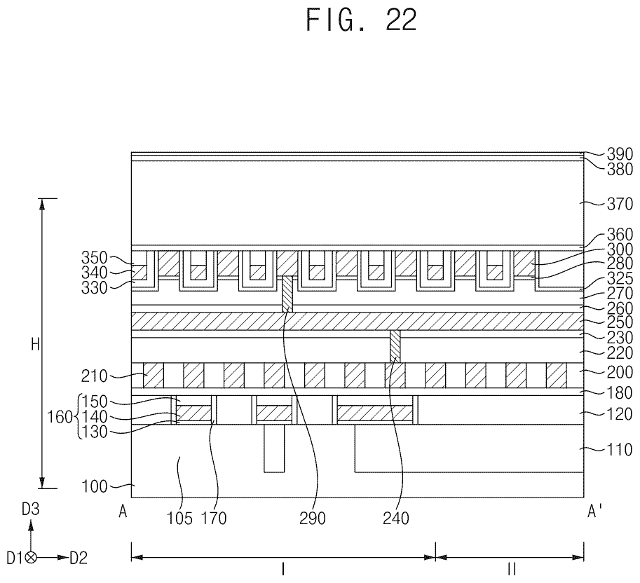

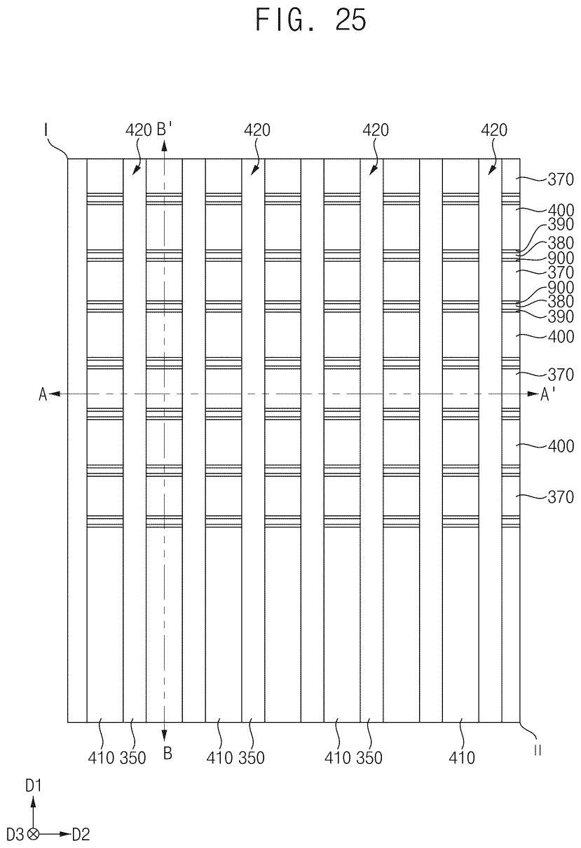

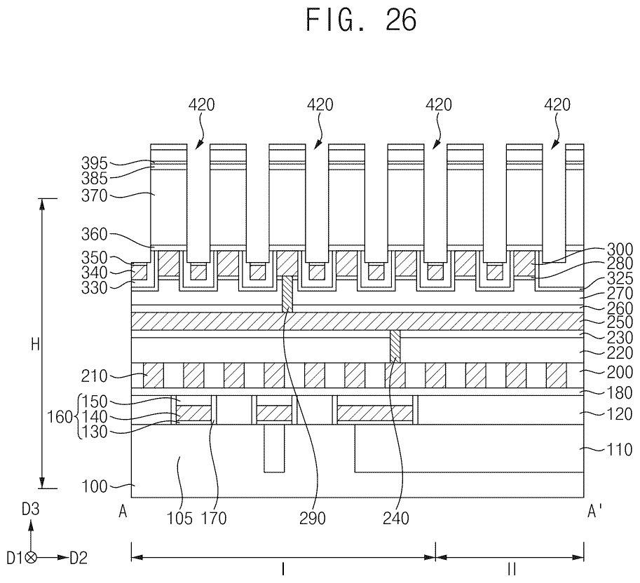

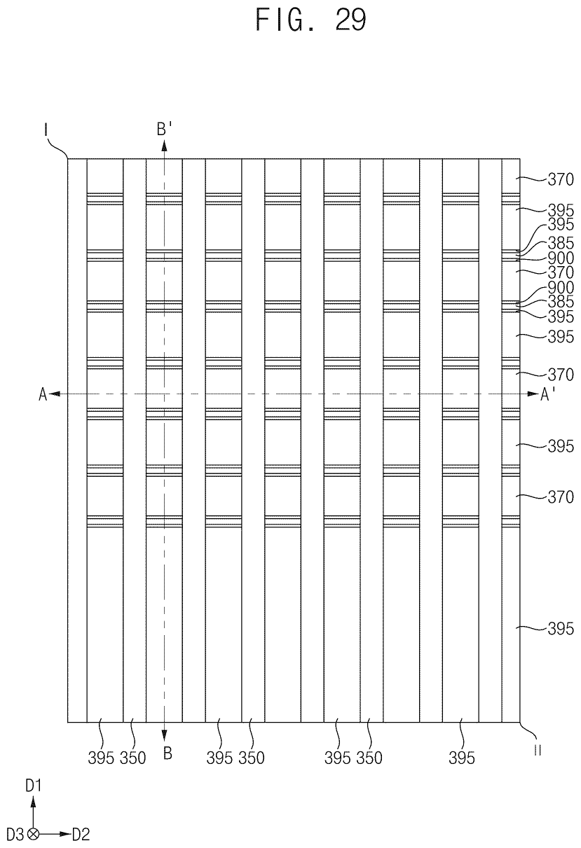

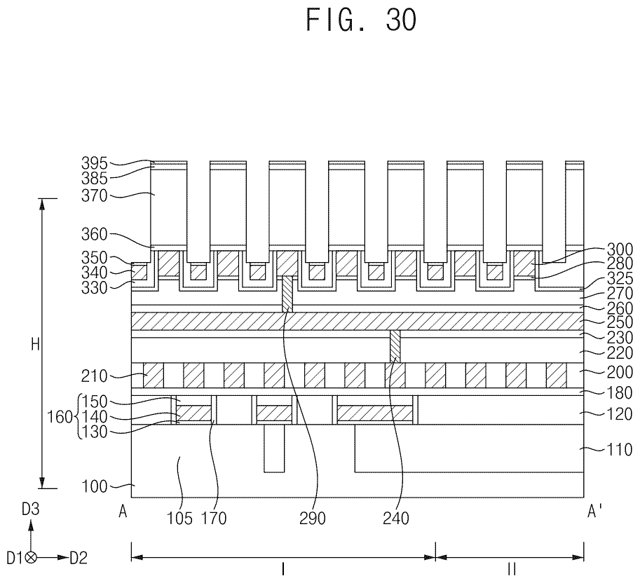

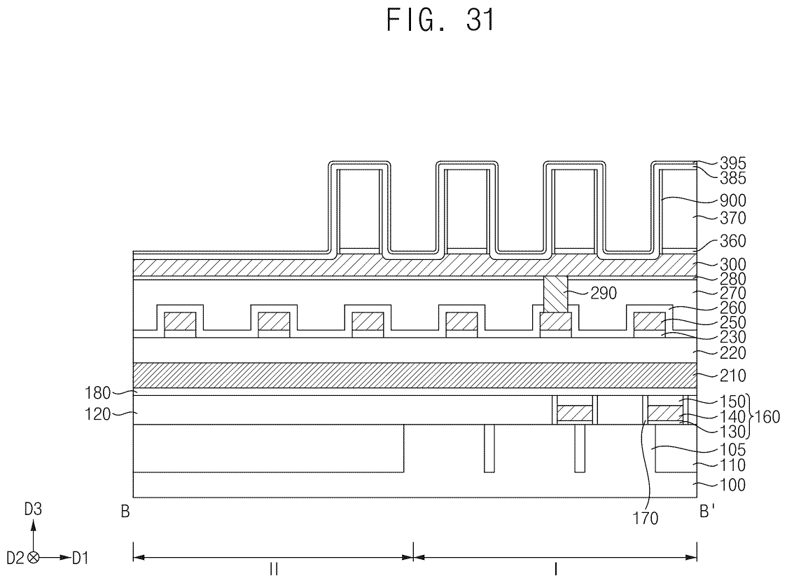

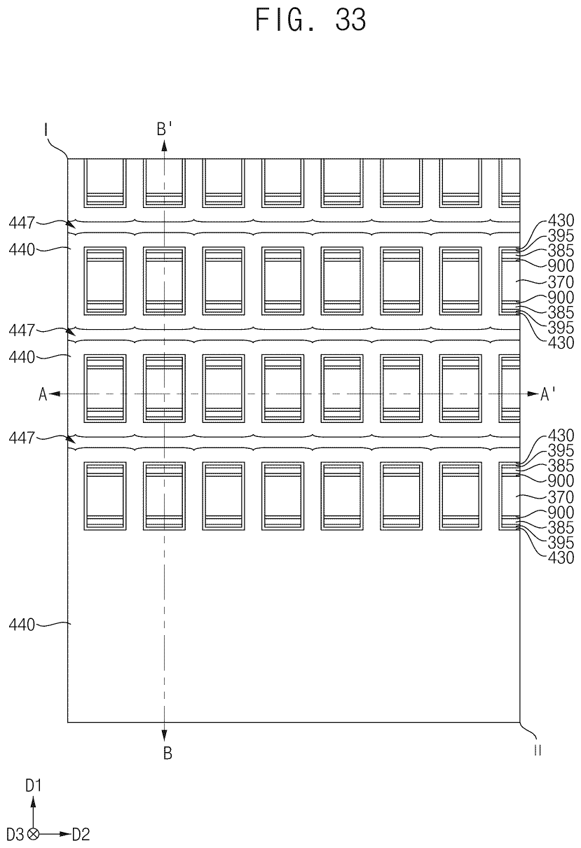

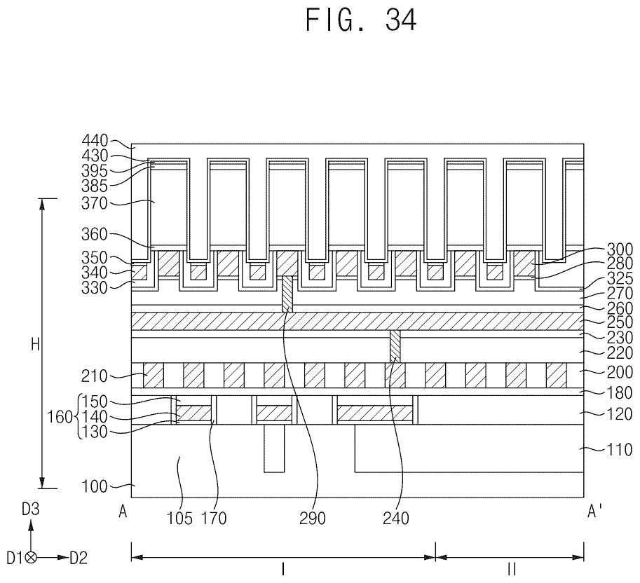

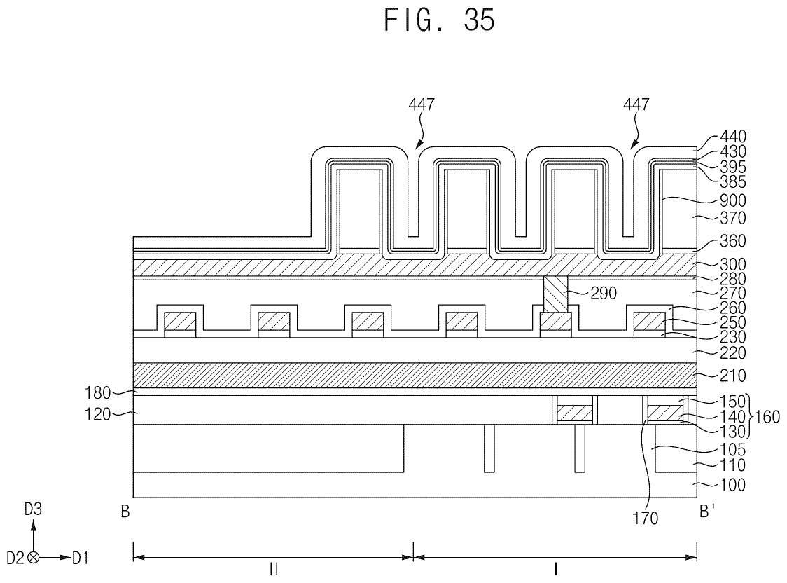

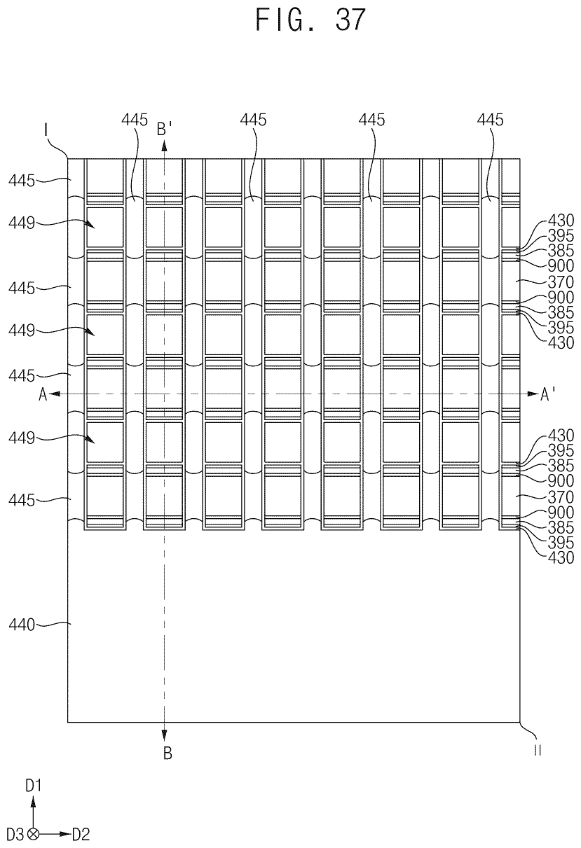

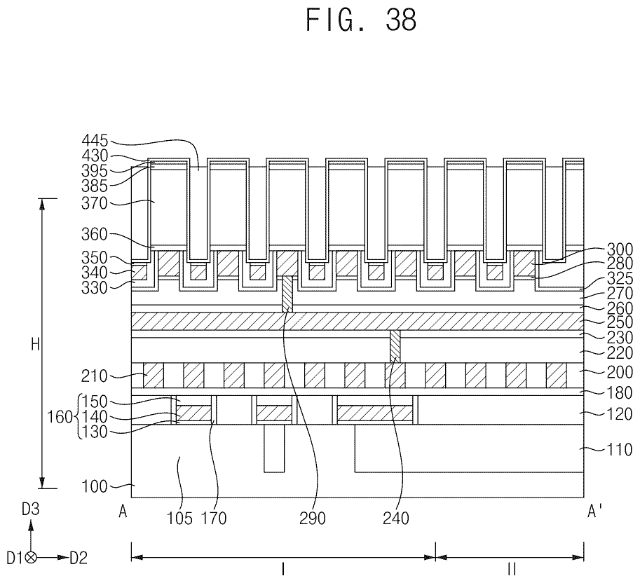

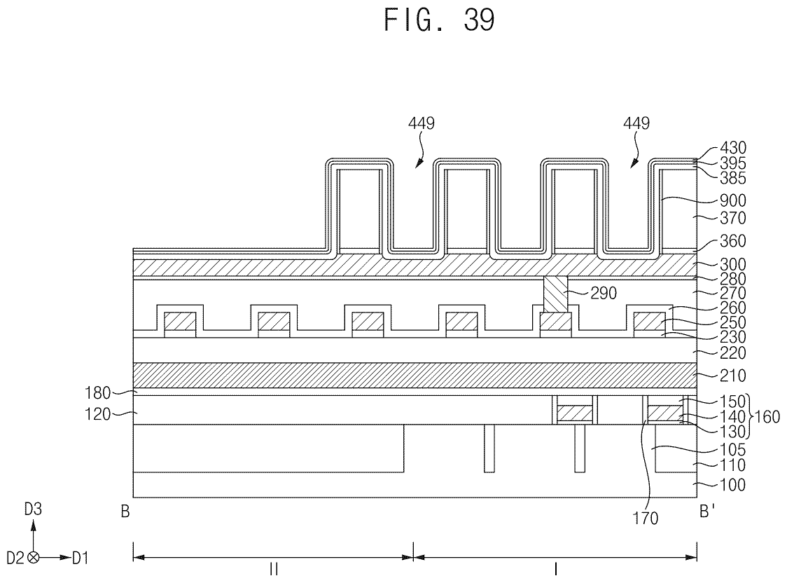

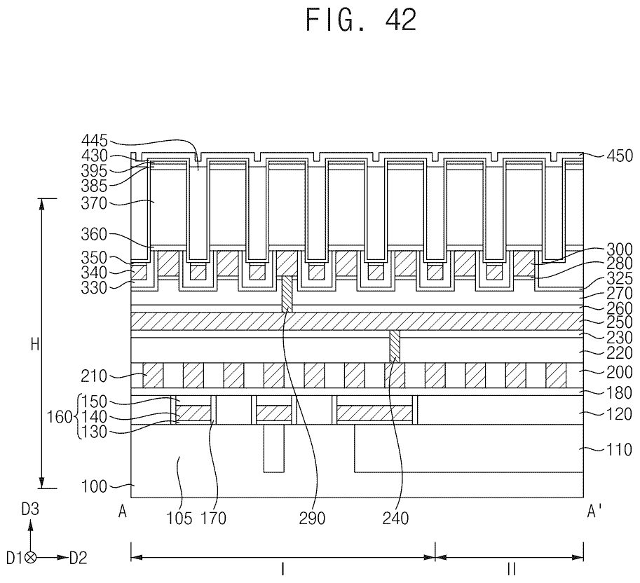

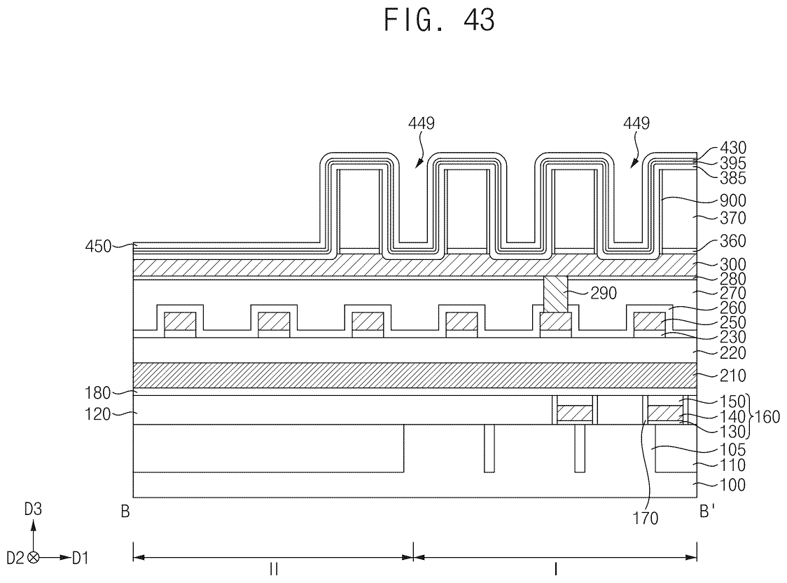

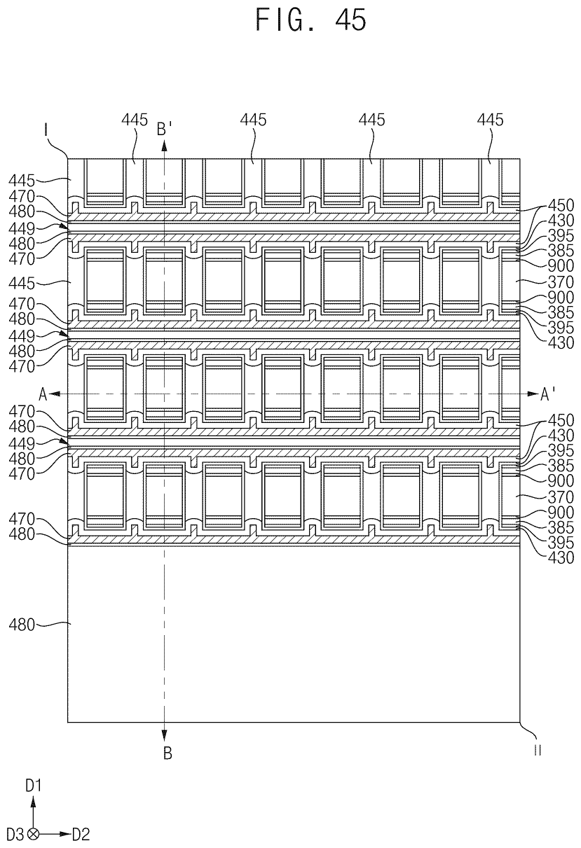

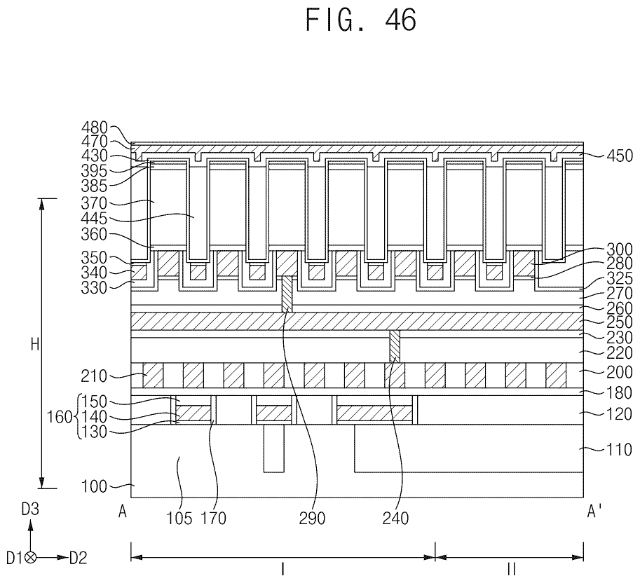

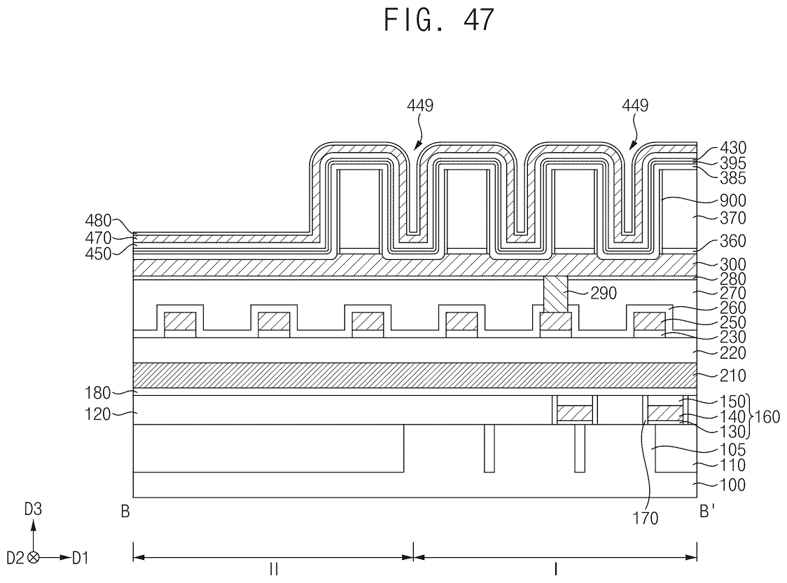

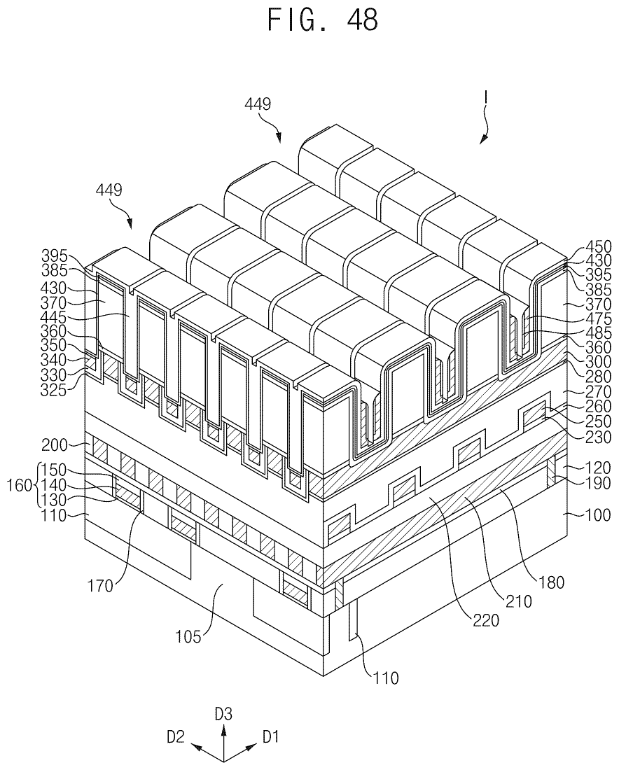

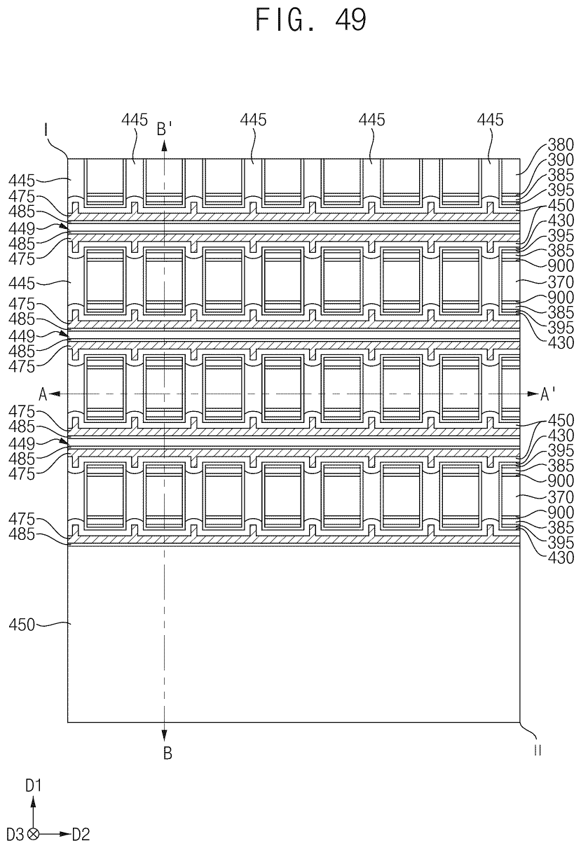

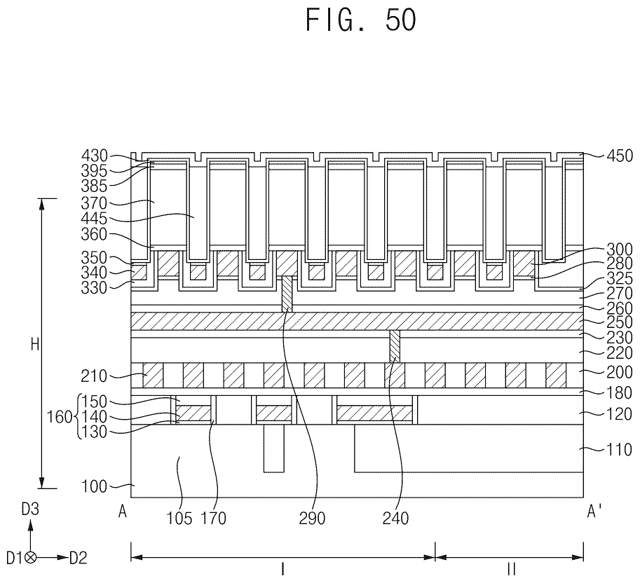

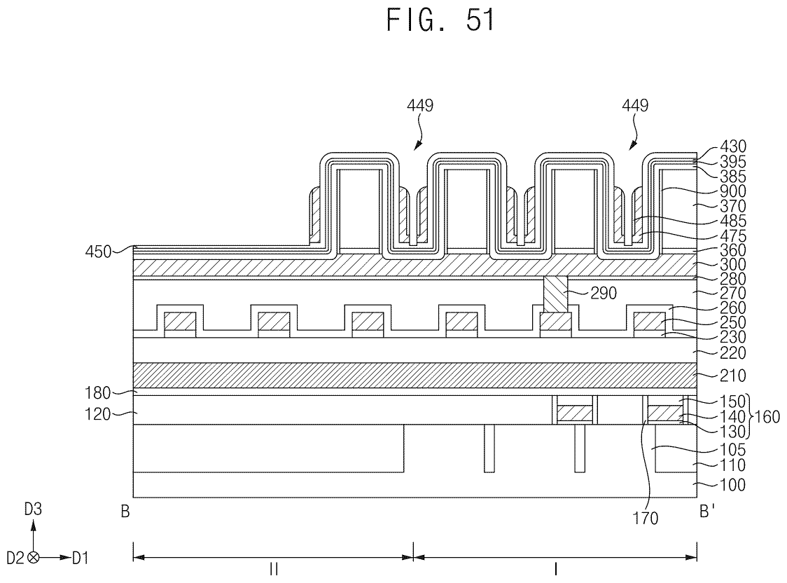

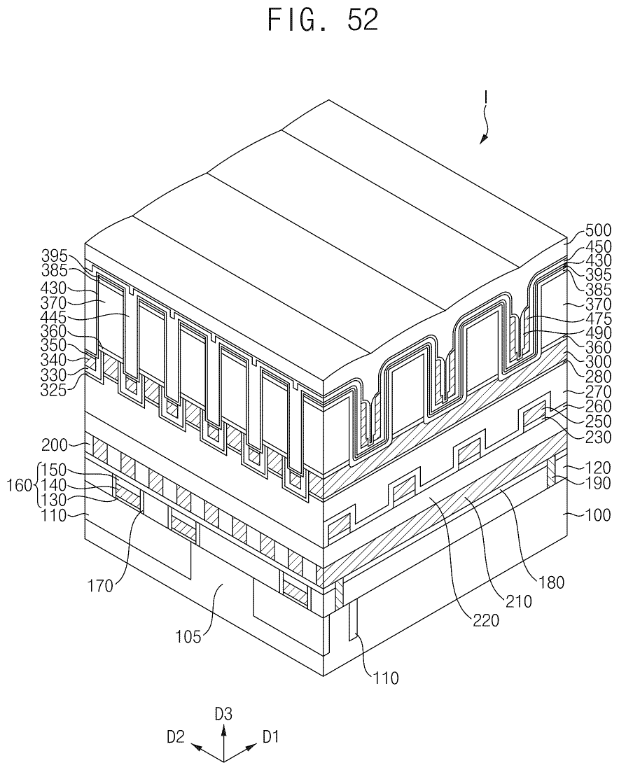

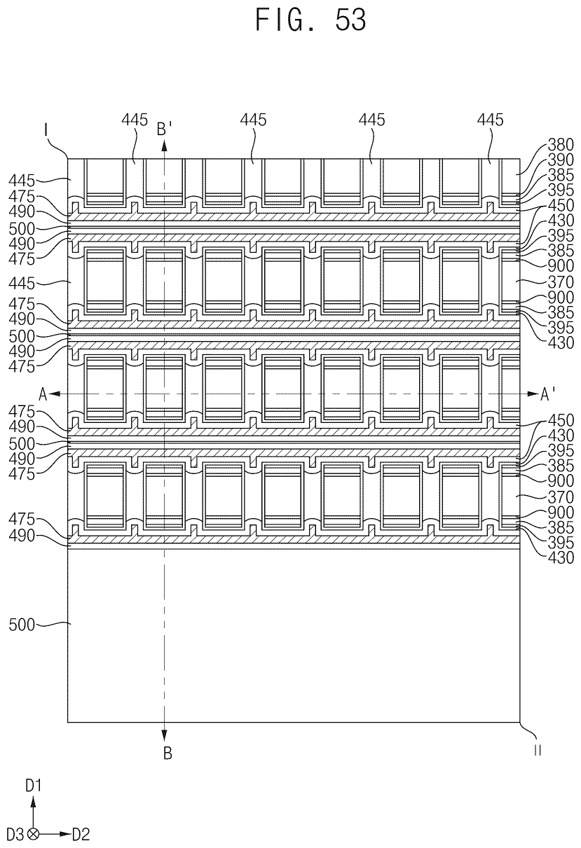

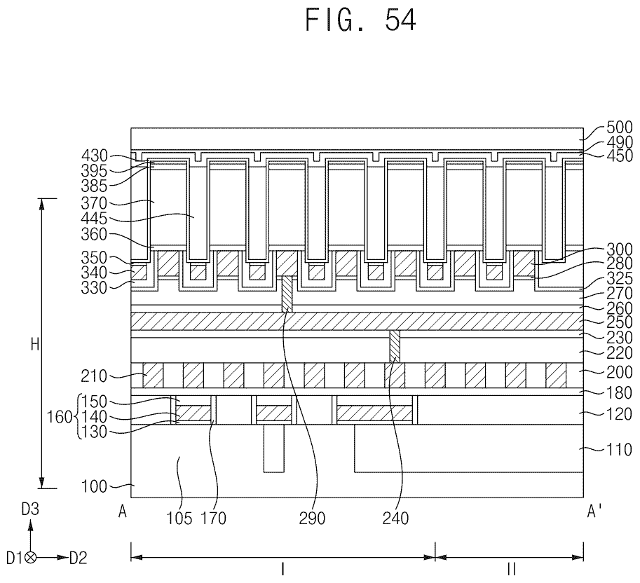

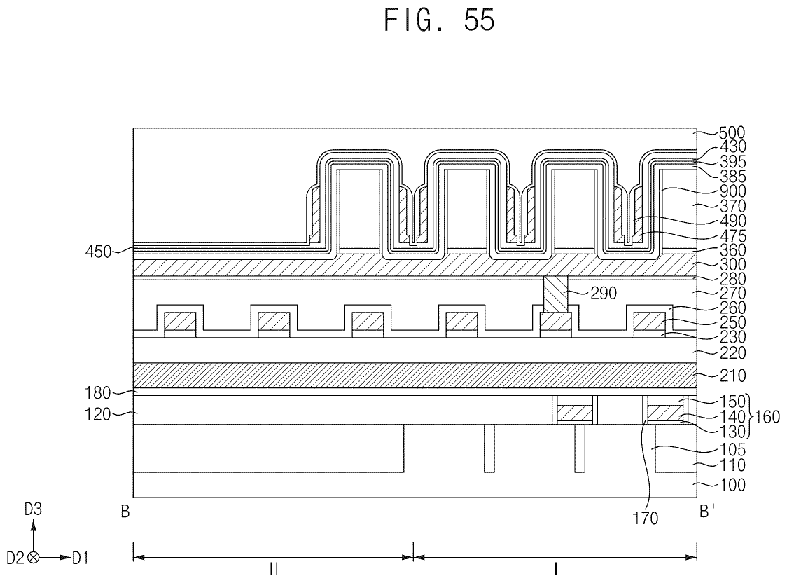

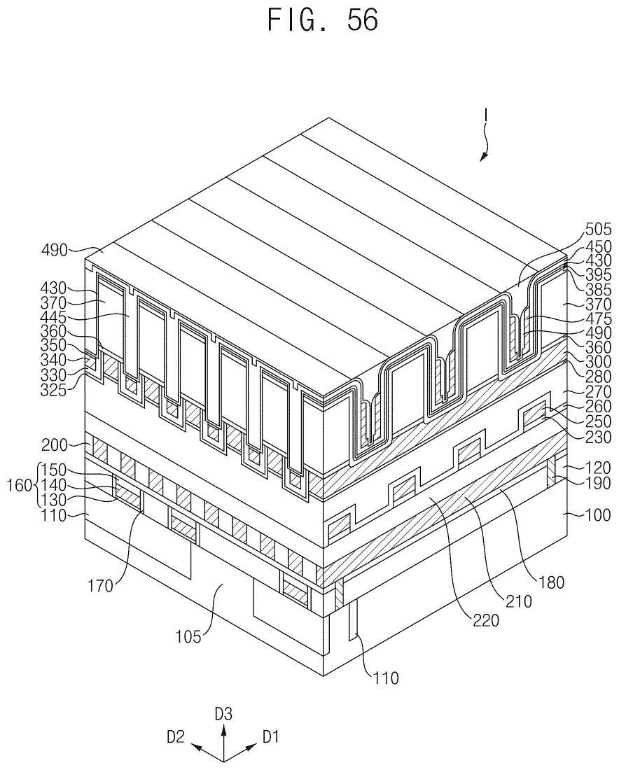

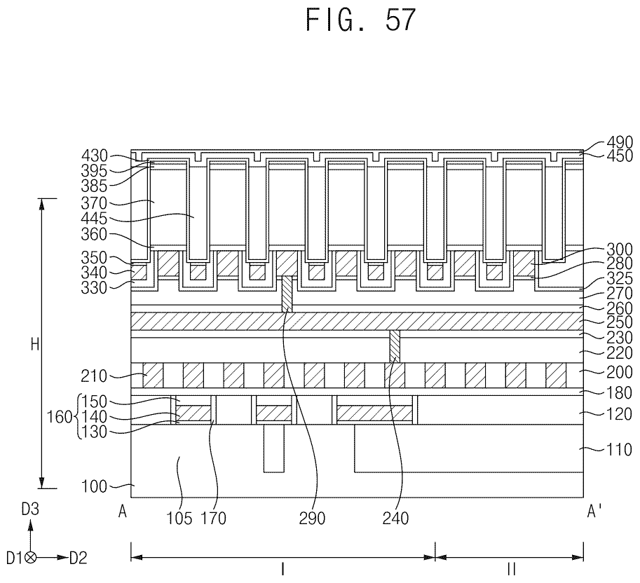

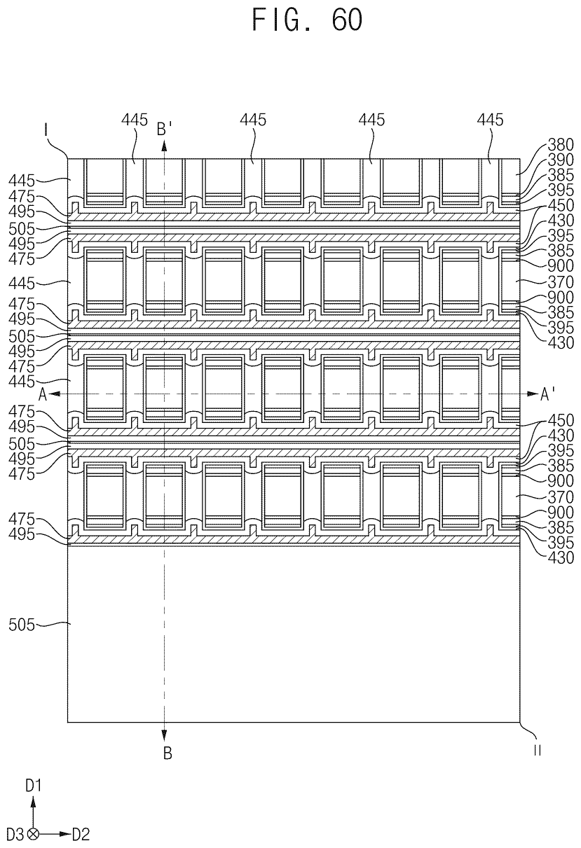

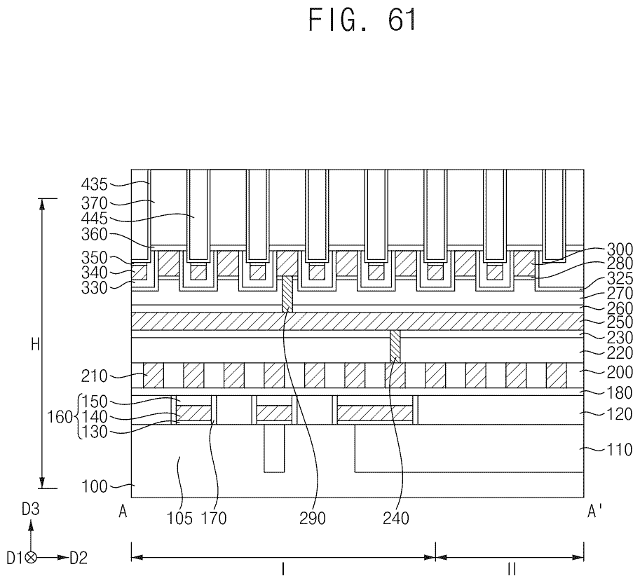

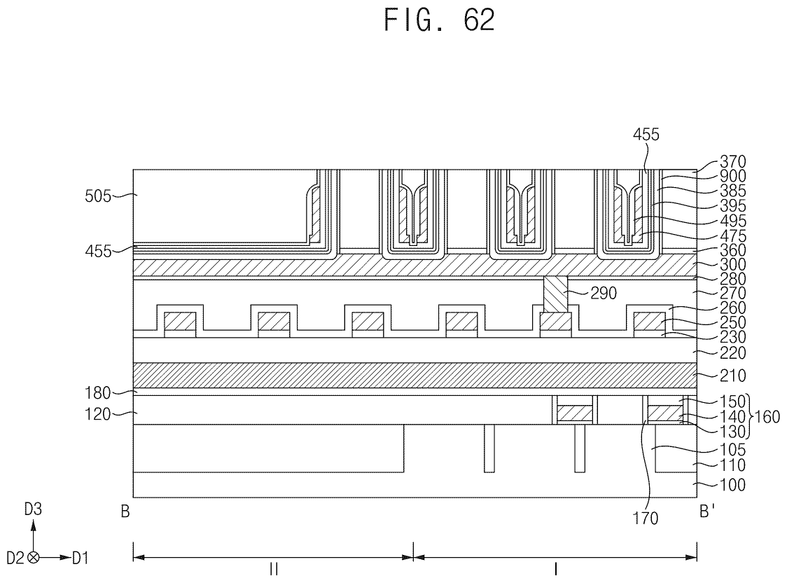

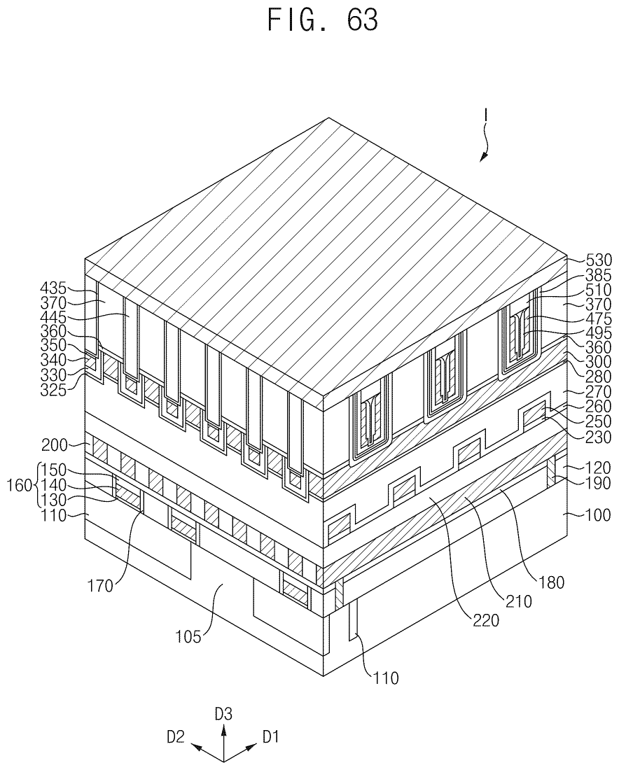

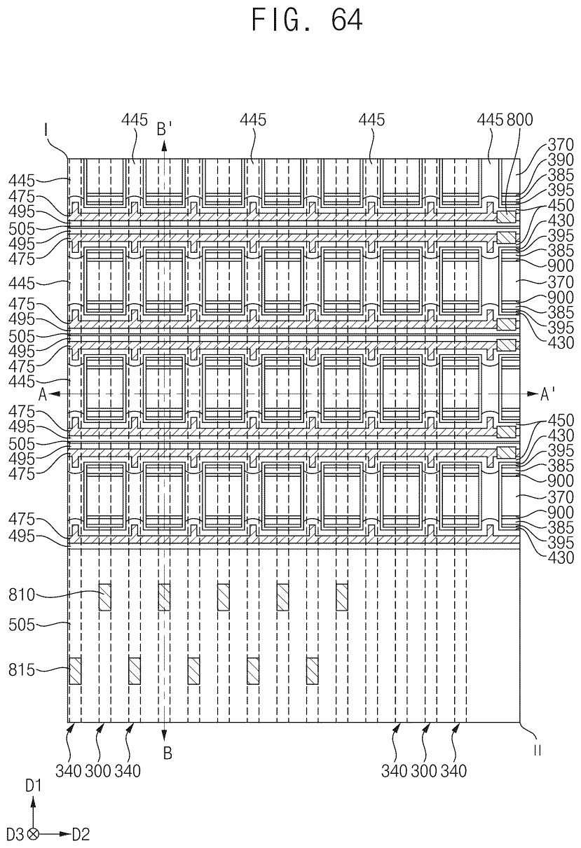

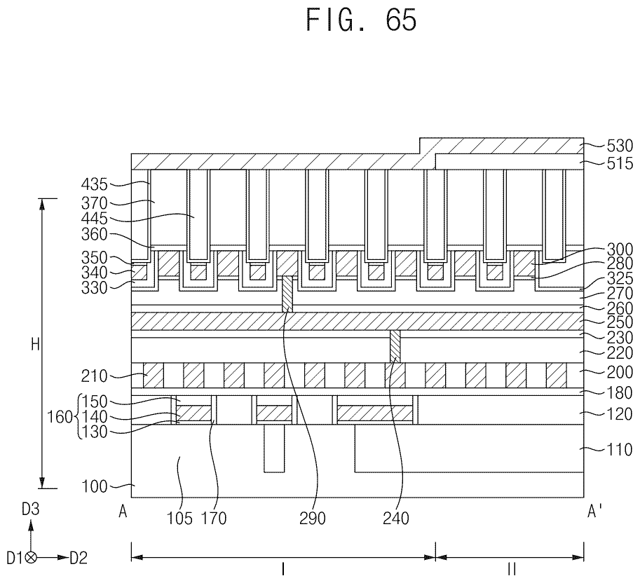

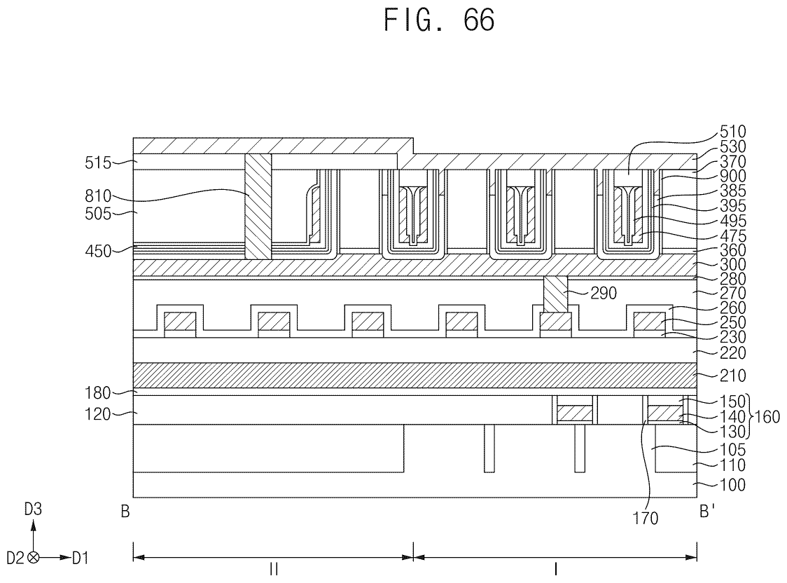

Specifically, among FIGS. 5 through 69: FIGS. 5, 9, 13, 16, 20, 24, 28, 32, 36, 40, 44, 48, 52, 56, 59, 63 and 67 are the perspective views; FIGS. 6, 10 and 17 are the plan views; FIGS. 21, 25, 29, 33, 37, 41, 45, 49, 53, 60 and 64 are the horizontal cross-sectional views; FIGS. 7, 11, 14, 18, 22, 26, 30, 34, 38, 42, 46, 50, 54, 57, 61, 65 and 68 are cross-sectional views taken along lines A-A′ of corresponding plan views or horizontal cross-sectional views, respectively; and FIGS. 8, 12, 15, 19, 23, 27, 31, 35, 39, 43, 47, 51, 55, 58, 62, 66 and 69 are cross-sectional views taken along lines B-B′ of corresponding plan views or horizontal cross-sectional views, respectively.

Each of the perspective views shows only the first region of the semiconductor device, and the horizontal cross-sectional views are drawings at a height H of corresponding vertical cross-sectional views, respectively. However, when an empty space exists at the height H, the horizontal cross-sectional view shows an element under the empty space.

Referring to FIGS. 5 through 8, an upper portion of a substrate 100 may be removed to form a first recess so that an active region 105 may be defined, and an isolation layer 110 may be formed to fill the first recess and to be disposed on a sidewall of the active region 105.

A first gate structure 160 may be formed on the active region 105 and the isolation layer 110, and a gate spacer 170 may be formed on a sidewall of the first gate structure 160. In one or more example embodiments, the first gate structure 160 may include a first gate insulation pattern 130, a first gate electrode 140 and a gate mask 150 sequentially stacked in the third direction D3.

Impurities may be implanted into an upper portion of the active region 105 adjacent to the first gate structure 160 to form a source/drain layer, and the first gate structure 160 and the source/drain layer may collectively form a transistor. In one or more example embodiments, the transistor may be a part of a sense amplifier (S/A).

A first insulating interlayer 120 may be formed on the active region 105 and the isolation layer 110 to be disposed on a sidewall of the gate spacer 170. A second insulating interlayer 180 may be formed on the first insulating interlayer 120, the first gate structure 160 and the gate spacer 170. A first contact plug 190 may extend through the first and second insulating interlayers 120 and 180 to contact an upper surface of the source/drain layer, and a second contact plug 195 may extend through the second insulating interlayer 180 and the gate mask 150 to contact an upper surface of the first gate electrode 140.

In one or more example embodiments, the first insulating interlayer 120 may include an oxide, e.g., silicon oxide, and the second insulating interlayer 180 may include an insulating nitride, e.g., silicon nitride.

A third insulating interlayer 200 may be formed on the second insulating interlayer 180, the first contact plug 190 and the second contact plug, and a first wiring 210 may be formed through the third insulating interlayer 200. In one or more example embodiments, the first wiring 210 may extend in the first direction D1, and a plurality of first wirings 210 may be spaced apart from each other in the second direction D2. Each of the first wirings 210 may contact an upper surface of a corresponding one of the first contact plug 190 and the second contact plug. In one or more example embodiments, the third insulating interlayer 200 may include an insulating nitride, e.g., silicon nitride, and thus, in some cases, may be merged with the second insulating interlayer 180.

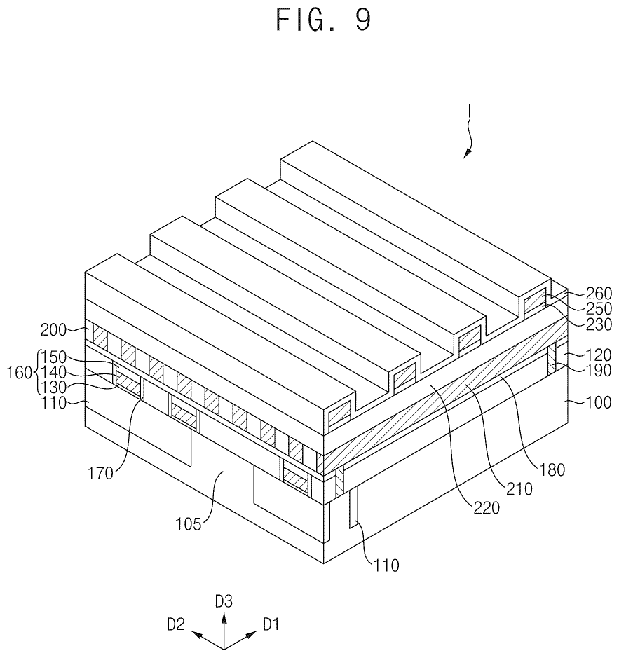

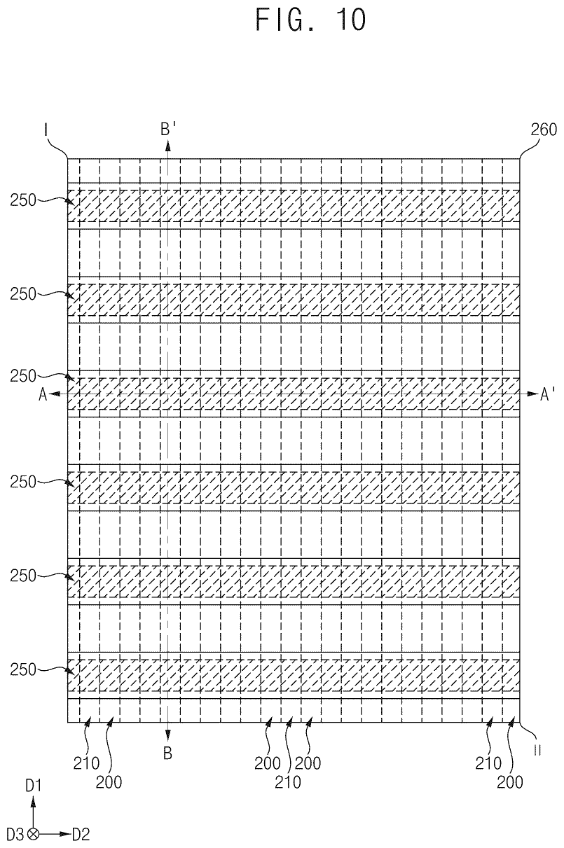

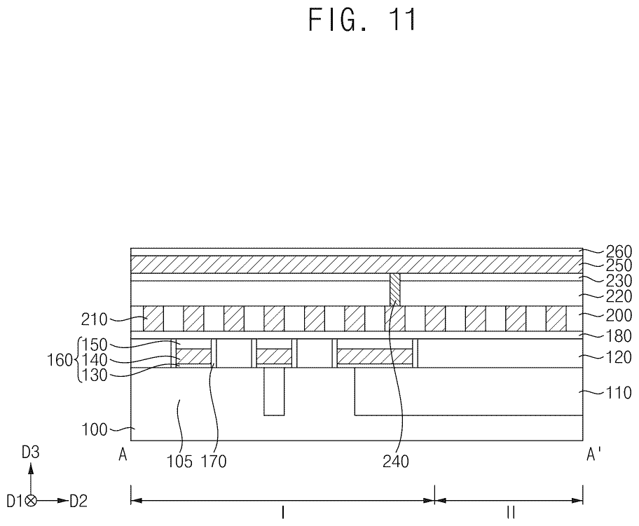

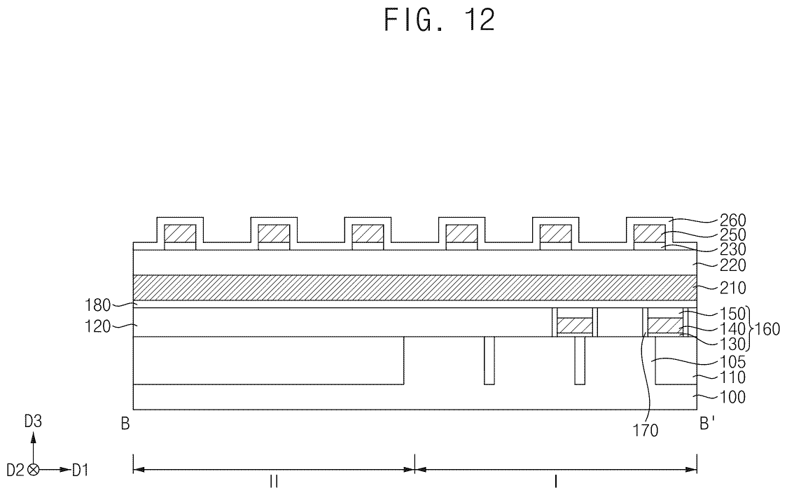

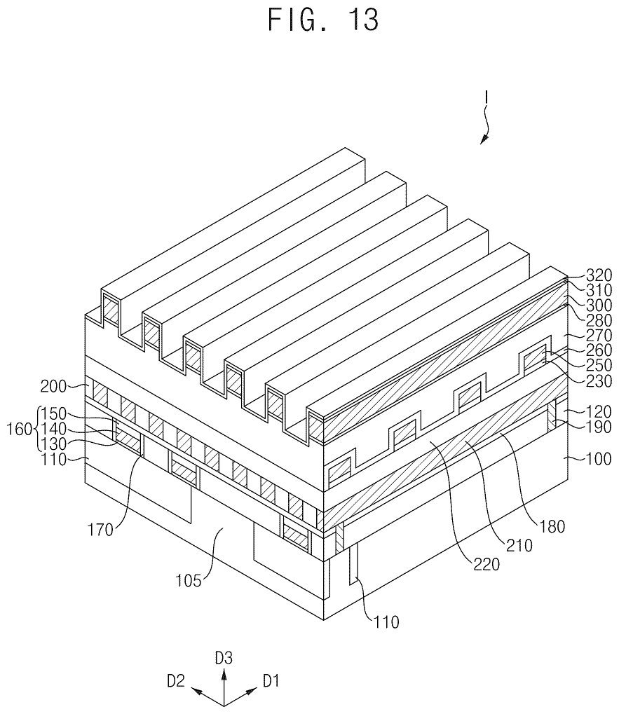

Referring to FIGS. 9 through 12, a fourth insulating interlayer 220 and a first insulation layer may be sequentially formed on the third insulating interlayer 200 and the first wiring 210, and a third contact plug 240 may be formed through the fourth insulating interlayer 220 to contact an upper surface of the first wiring 210.

In one or more example embodiments, the fourth insulating interlayer 220 may include an oxide, e.g., silicon oxide, and the first insulation layer may include an insulating nitride, e.g., silicon nitride.

A second wiring layer may be formed on the first insulation layer and the third contact plug 240, and the second wiring layer and the first insulation layer may be patterned to form a second wiring 250 and a first insulation pattern 230, respectively. In one or more example embodiments, the second wiring 250 may extend in the second direction D2, and a plurality of second wirings 250 may be spaced apart from each other in the first direction D1. Each of the second wirings 250 may contact an upper surface of the third contact plug 240.

A second insulation layer 260 may be formed on the second wiring 250 and the first insulation pattern 230. In one or more example embodiments, the second insulation layer 260 may include an insulating nitride, and thus, in some cases, may be merged with the first insulation pattern 230.

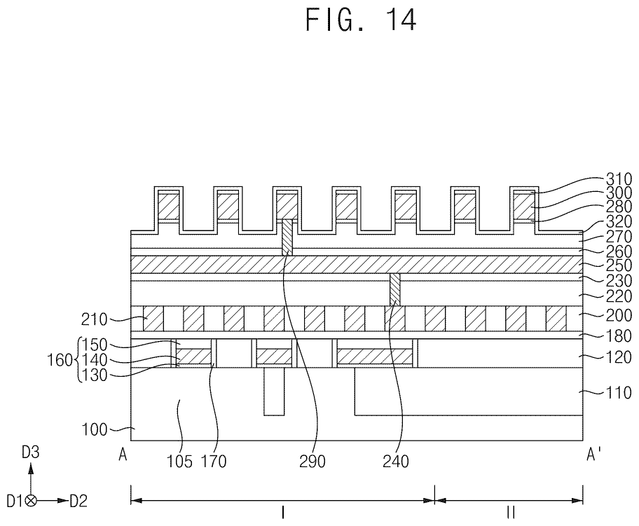

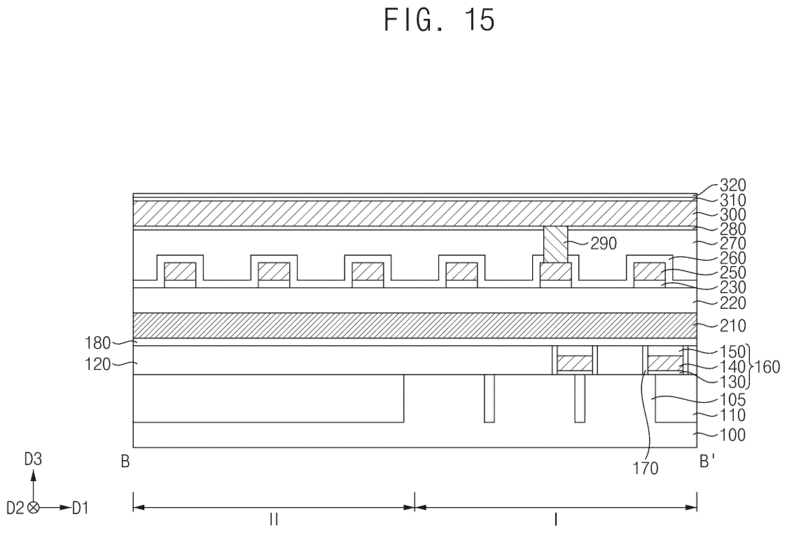

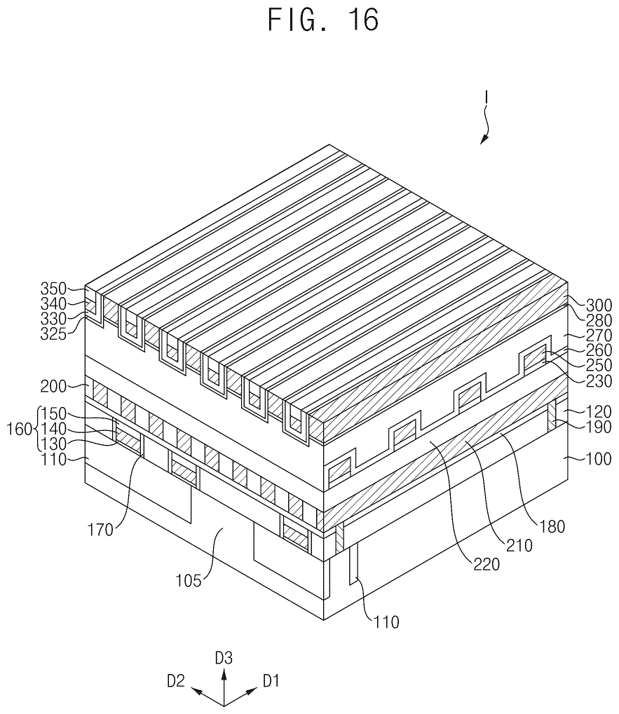

Referring to FIGS. 13 through 15, a fifth insulating interlayer 270 and a third insulation layer may be sequentially stacked on the second insulation layer 260, and a fourth contact plug 290 may be formed through the third insulation layer, an upper portion of the fifth insulating interlayer 270 and the second insulation layer 260 to contact an upper surface of the second wiring 250.

A fourth contact plug 290, a third wiring layer and a fourth insulation layer may be sequentially stacked on the third insulation layer, and an etching process may be performed on the fourth insulation layer, the third wiring layer and the third insulation layer to form a fourth insulation pattern 310, a third wiring 300 and a third insulation pattern 280, respectively, and during the etching process, an upper portion of the fifth insulating interlayer 270 may also be removed.

In one or more example embodiments, the third wiring 300 may extend in the first direction D1, and a plurality of third wirings 300 may be spaced apart from each other in the second direction D2. Each of the third wirings 300 may be electrically connected to the second wiring 250 through the fourth contact plug 290. In one or more example embodiments, each of the third wirings 300 may serve as a bit line, and one or more of the third wirings 300 on the second region II of the substrate 100 may be a dummy bit line.

In one or more example embodiments, the fifth insulating interlayer 270 may include an oxide, e.g., silicon oxide, and each of the third and fourth insulation patterns 280 and 310 may include an insulating nitride, e.g., silicon nitride.

A fifth insulation layer 320 may be formed on the fifth insulating interlayer 270, the third and fourth insulation patterns 280 and 310 and the third wiring 300. In one or more example embodiments, the fifth insulation layer 320 may include an insulating nitride, e.g., silicon nitride, and thus, in some cases, may be merged with the third and/or fourth insulation patterns 280 and 310.

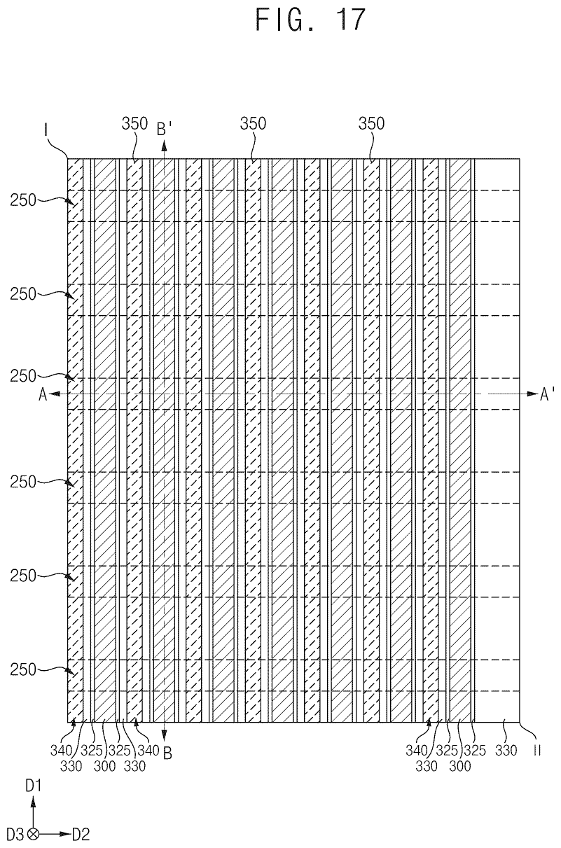

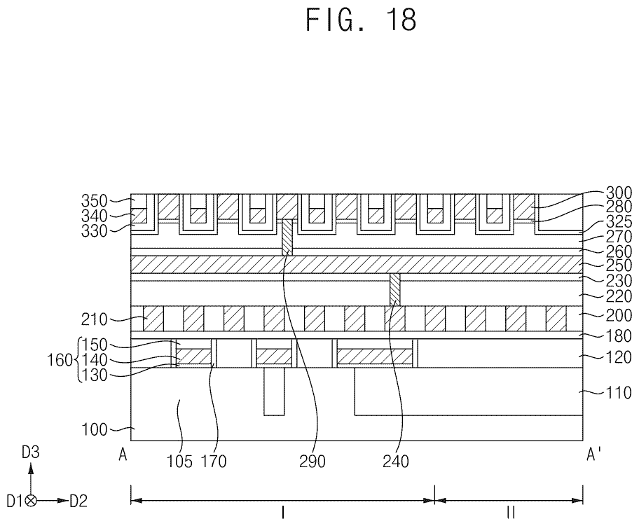

Referring to FIGS. 16 through 18, a sixth insulation layer and a fourth wiring layer may be sequentially formed on the fifth insulation layer 320, and an upper portion of the fourth wiring layer may be removed by, for example, an etch back process to form a fourth wiring 340.

A seventh insulation layer may be formed on the fourth wiring 340 and the sixth insulation layer, and a planarization process may be performed on the sixth and seventh insulation layers until an upper surface of the third wiring 300 is exposed to form sixth and seventh insulation patterns 330 and 350, respectively.

During the planarization process, an upper portion of the fifth insulation layer 320 may be removed to form a plurality of fifth insulation patterns 325 spaced apart from each other in the second direction D2, and the fourth insulation pattern 310 may be removed. Each of the sixth and seventh insulation patterns 330 and 350 and the fourth wiring 340 may extend in the first direction D1. A plurality of sixth insulation patterns 330 may be spaced apart from each other in the second direction D2, a plurality of seventh insulation patterns 350 may be spaced apart from each other in the second direction D2, and a plurality of fourth wirings 340 may be spaced apart from each other in the second direction D2. In one or more example embodiments, the fourth wiring 340 may be disposed adjacent to the third wiring 300 serving as a bit line, and may serve as a bit line shield. A cross-section in the second direction D2 of each of the fifth and sixth insulation patterns 325 and 330 may have a shape of a cup.

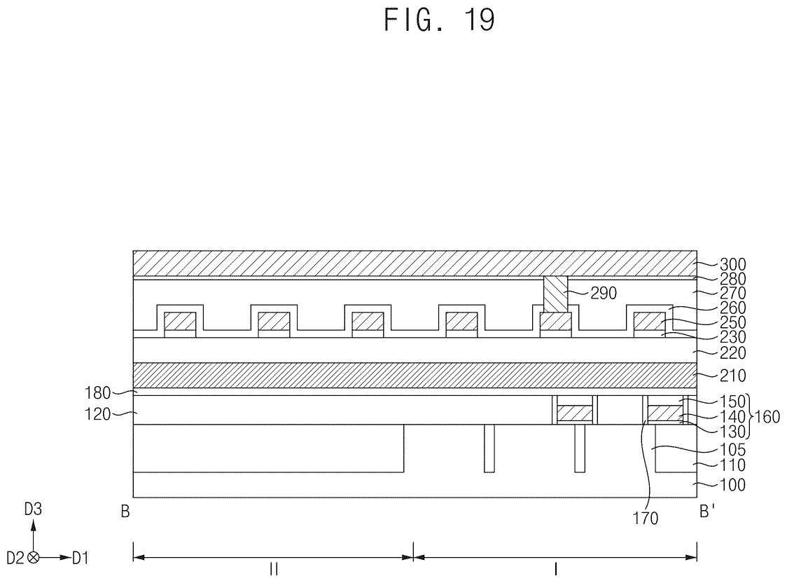

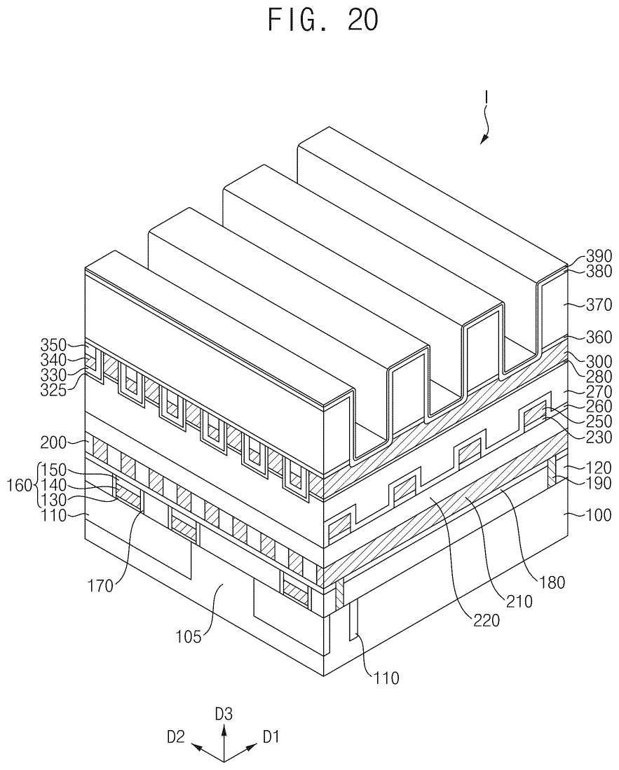

Referring to FIGS. 20 to 23, an eighth insulation layer and a first mold layer may be sequentially formed on the fifth to seventh insulation patterns 325, 330 and 350 and the third wiring 300, and the first mold layer and the eighth insulation layer may be patterned by an etching process to form a first mold 370 and an eighth insulation pattern 360, respectively, and during the etching process, upper portions of the fifth to seventh insulation patterns 325, 330 and 350 and the third wiring 300 may also be removed.

In one or more example embodiments, each of the first mold 370 and the eighth insulation pattern 360 may extend in the second direction D2. A plurality of first molds 370 may be spaced apart from each other in the first direction D1, and a plurality of eighth insulation patterns 360 may be spaced apart from each other in the first direction D1.

In one or more example embodiments, the first mold 370 may include a low density material such as a porous material, e.g., silicon oxide doped with carbon (SiOCH) (which may also be referred to as organic silicate glass) or silicon carbonitride (SiCN).

An interface layer may be formed on the first mold 370 and the eighth insulation pattern 360, and an anisotropic etching process may be performed on the interface layer to form an interface pattern 900 on a sidewall in the first direction D1 of each of the first mold 370 and the eighth insulation pattern 360. In one or more example embodiments, the interface layer may be formed by, e.g., an atomic layer deposition (ALD) process, and may include an oxide, e.g., silicon oxide.

A channel layer 380 may be formed on the interface pattern 900, the first mold 370, the fifth to seventh insulation patterns 325, 330 and 350 and the third wiring 300, and a first capping layer 390 may be formed on the channel layer 380.

In one or more example embodiments, the channel layer 380 may include an oxide semiconductor material, e.g., Indium gallium zinc oxide (IGZO), and the first capping layer 390 may include an insulating material, e.g., silicon nitride, silicon oxide, silicon oxycarbide, silicon oxycarbonitride, aluminum oxide, etc.

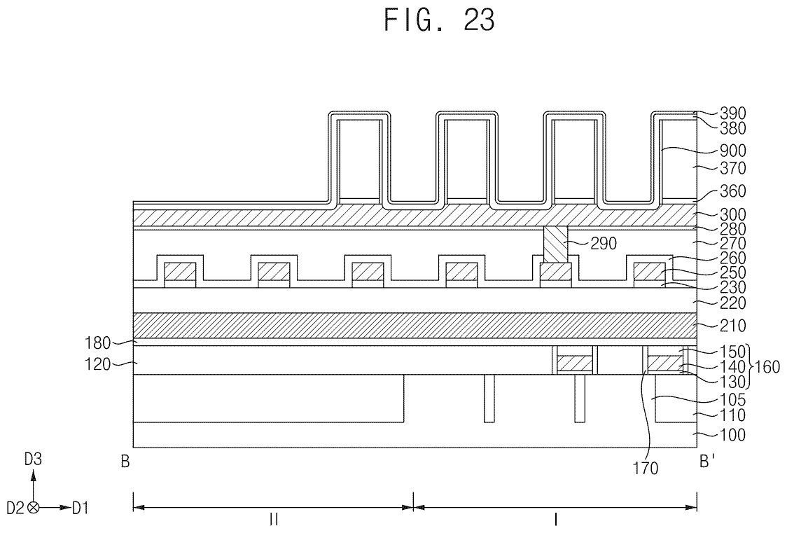

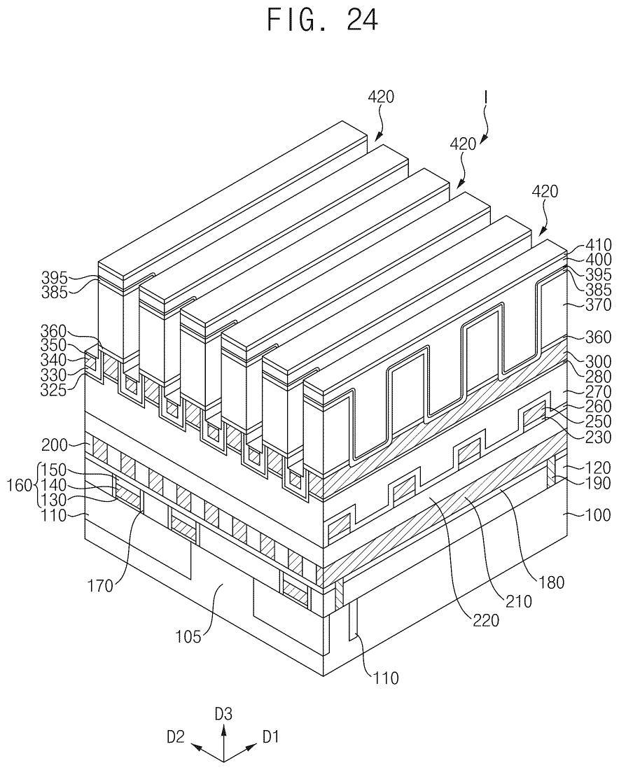

Referring to FIGS. 24 through 27, a second mold layer and a mask layer may be sequentially formed on the first capping layer 390, the mask layer may be patterned to form a plurality of masks 410, each of which may extend in the first direction D1, spaced apart from each other in the second direction D2, and a dry etching process may be performed using the mask 410 as an etching mask to pattern the second mold layer, the first capping layer 390, the channel layer 380, the first mold 370 and the eighth insulation pattern 360, so that a first opening 420 may be formed to expose an upper surface of the seventh insulation pattern 350.

Thus, the second mold layer may be divided into a plurality of second molds 400, each of which may extend in the first direction D1, spaced apart from each other in the second direction D2. The first capping layer 390 may be divided into first capping patterns 395, each of which may extend in the first direction D1, spaced apart from each other in the second direction D2, and the channel layer 380 may be divided into channels 385, each of which may extend in the first direction D1, spaced apart from each other in the second direction D2. The first mold 370 extending in the second direction D2 may be divided into a plurality of parts spaced apart from each other in the second direction D2, and the eighth insulation pattern 360 extending in the second direction D2 may be divided into a plurality of parts spaced apart from each other in the second direction D2.

The second mold 400 may include, e.g., spin-on-hardmask (SOH) or amorphous carbon layer (ACL), and the mask 410 may include, e.g., silicon nitride.

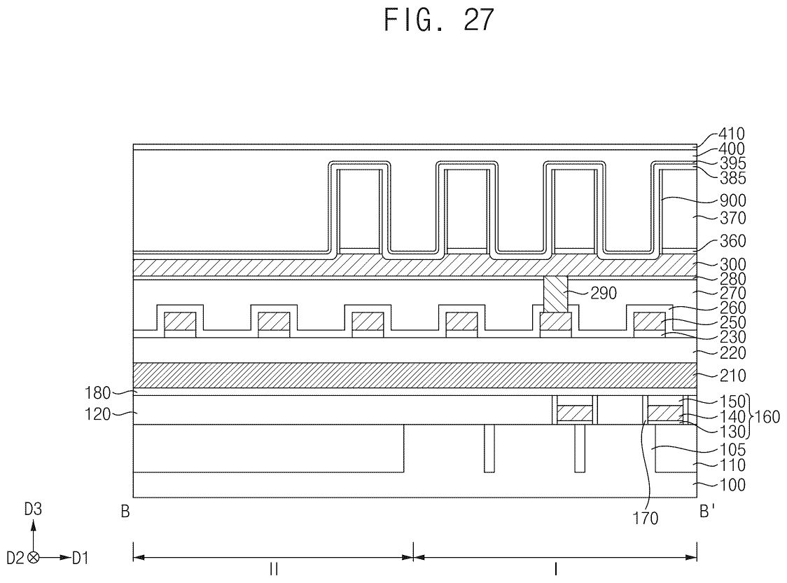

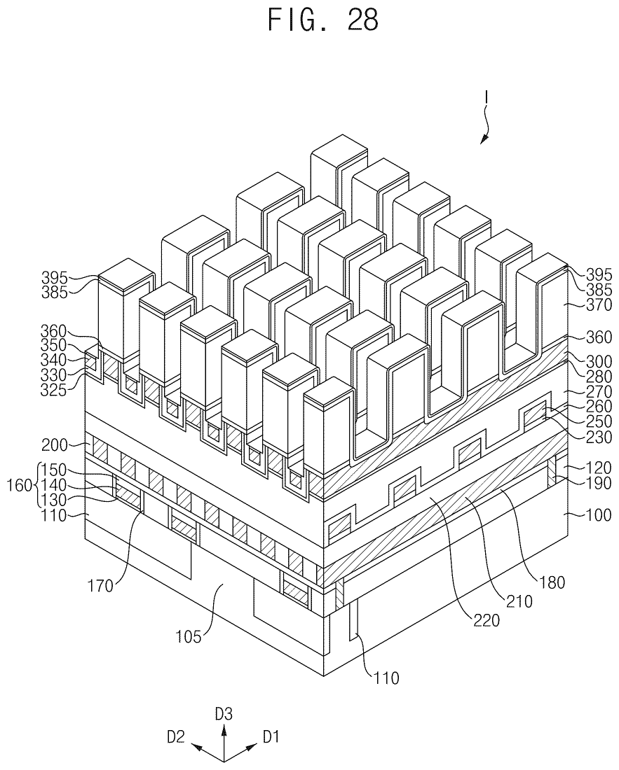

Referring to FIGS. 28 through 31, the mask 410 and the second mold 400 may be removed, and thus an upper surface of the first capping pattern 395 may be exposed.

In one or more example embodiments, the mask 410 may be removed by an etching process, and the second mold 400 may be removed by, e.g., an ashing process and/or a stripping process. During the removal of the second mold 400, the first capping pattern 395 may be formed on the channel 385 to prevent the channel 385 from being damaged.

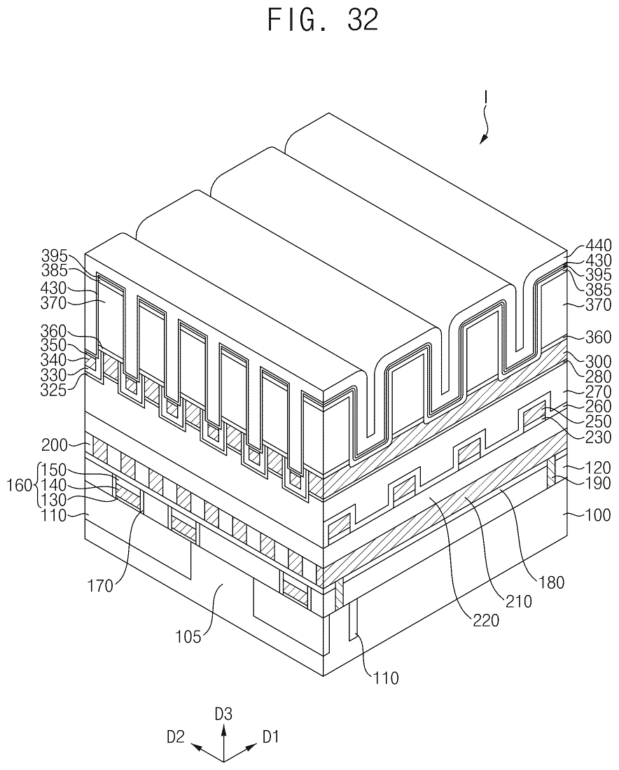

Referring to FIGS. 32 through 35, a second capping layer 430 may be formed on the first capping pattern 395, the channel 385, the first mold 370 and the seventh and eighth insulation patterns 350 and 360, and a sixth insulating interlayer 440 may be formed on the second capping layer 430.

The second capping layer 430 may include an insulating nitride, e.g., silicon nitride, silicon oxide, silicon oxycarbide, silicon oxycarbonitride, aluminum oxide, etc. In one or more example embodiments, the second capping layer 430 may include substantially the same material as the first capping pattern 395, and thus may be merged with the first capping pattern 395.

In one or more example embodiments, the sixth insulating interlayer 440 may fill a portion of the first opening 420 between stack structures, each of which may include the eighth insulation pattern 360, the first mold 370, the channel 385, the first capping pattern 395 and a portion of the second capping layer 430 on upper surfaces and sidewalls of the eighth insulation pattern 360, the first mold 370, the channel 385 and the first capping pattern 395, and may be formed on each of opposite sidewalls of the stack structure in the first direction D1. A plurality of second recesses 447, each of which may extend in the second direction D2, spaced apart from each other in the first direction D1 may be formed on a portion of the sixth insulating interlayer 440 between the stack structures spaced apart from each other in the first direction D1.

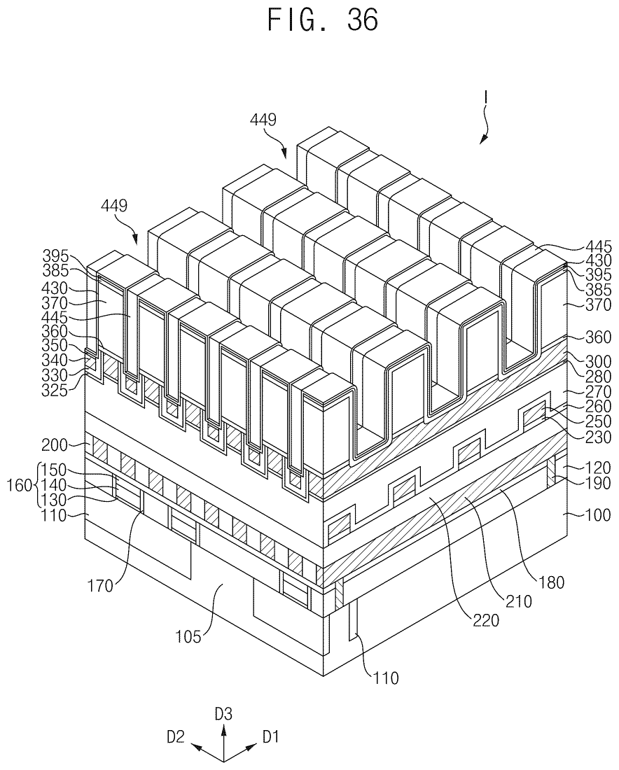

Referring to FIGS. 36 through 39, an isotropic etching process such as a wet etching process may be performed on the sixth insulating interlayer 440 to form a sixth insulating interlayer pattern 445.

In one or more example embodiments, as the isotropic etching process is performed, an upper surface of the second capping layer 430 may be exposed, and most portion of the portion of the sixth insulating interlayer 440 between the stack structures spaced apart from each other in the first direction D1 may be removed, and an upper portion of a portion of the sixth insulating interlayer 440 between the stack structures spaced apart from each other in the second direction D2 may be removed.

Thus, in one or more example embodiments, an upper surface of the sixth insulating interlayer pattern 445 may be lower than an upper surface of the channel 385 and higher than a lower surface of the channel 385, however the disclosure is not limited thereto.

During the isotropic etching process, the channel 385 may be protected by the first capping pattern 395 and the second capping layer 430 not to be damaged.

The second recess 447 may be enlarged to a third recess 449 having width and depth greater than those of the second recess 447.

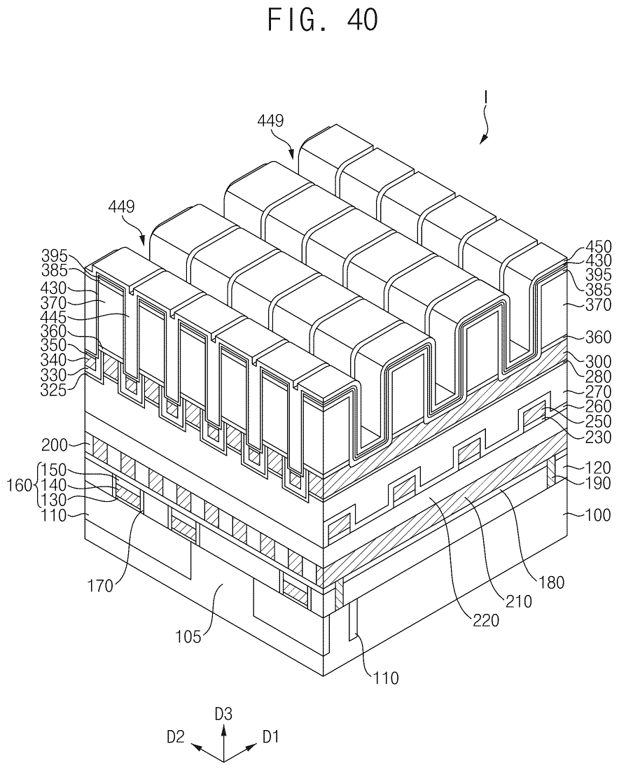

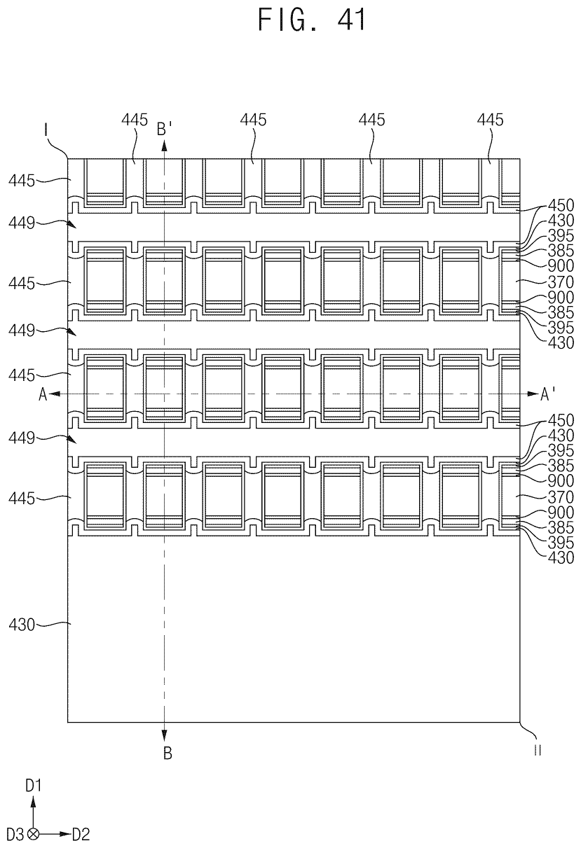

Referring to FIGS. 40 through 43, a second gate insulation layer 450 may be formed on the second capping layer 430 and the sixth insulating interlayer pattern 445.

The second gate insulation layer 450 may include an insulating nitride, e.g., silicon nitride, silicon oxide, silicon oxycarbide, silicon oxycarbonitride, aluminum oxide, etc. In one or more example embodiments, the second gate insulation layer 450 may include substantially the same material as the second capping layer 430, and thus may be merged with the second capping layer 430.

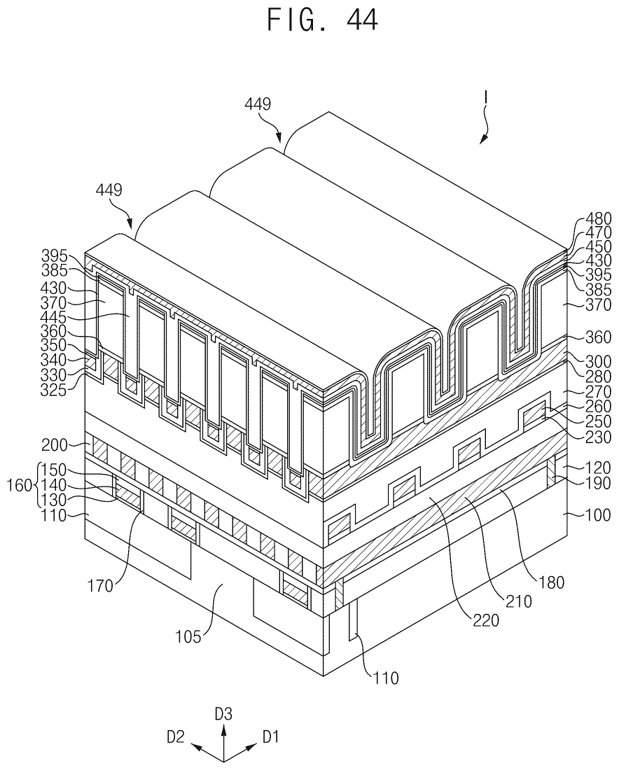

Referring to FIGS. 44 through 47, a second gate electrode layer 470 and a third capping layer 480 may be sequentially formed on the second gate insulation layer 450.

The third capping layer 480 may include an insulating nitride, e.g., silicon nitride.

Referring to FIGS. 48 through 51, an anisotropic etching process may be performed on the third capping layer 480 and the second gate electrode layer 470 to form a third capping pattern 485 and a second gate electrode 475, respectively.

In one or more example embodiments, each of the third capping pattern 485 and the second gate electrode 475 may be disposed on a sidewall of the second gate insulation layer 450, and may have a ring shape in a plan view. Each of the third capping pattern 485 and the second gate electrode 475 may include first portions, each of which may extend in the second direction D2, opposite to each other in the first direction D1, and second portions extending in the first direction D1 and connecting the first portions to each other. A plurality of third capping patterns 485 may be spaced apart from each other in the first direction D1, and a plurality of second gate electrodes 475 may be spaced apart from each other in the first direction D1.

Each of the second gate electrodes 475 may be formed on a portion of the second gate insulation layer 450 on a sidewall in the first direction D1 of each of the stack structures neighboring in the first direction D1, and the second gate electrodes 475 in the third recess 449 may face each other in the first direction D1. An upper surface and a sidewall of an upper portion of the second gate insulation layer 450 and an upper surface of a portion of the second gate insulation layer 450 on a bottom of the third recess 449 may be exposed by the anisotropic etching process.

The second gate electrode 475 may be formed on a sidewall and a lower surface of the third capping pattern 485.

Referring to FIGS. 52 through 55, a first etch stop layer 490 may be formed on the second gate insulation layer 450, the second gate electrode 475, and the third capping pattern 485, and a seventh insulating interlayer 500 may be formed on the first etch stop layer 490 to fill the third recess 449.

The first etch stop layer 490 may include an insulating nitride, e.g., silicon nitride. In one or more example embodiments, the first etch stop layer 490 may include substantially the same material as the third capping pattern 485, and thus may be merged with the third capping pattern 485. The seventh insulating interlayer 500 may include an oxide, e.g., silicon oxide.

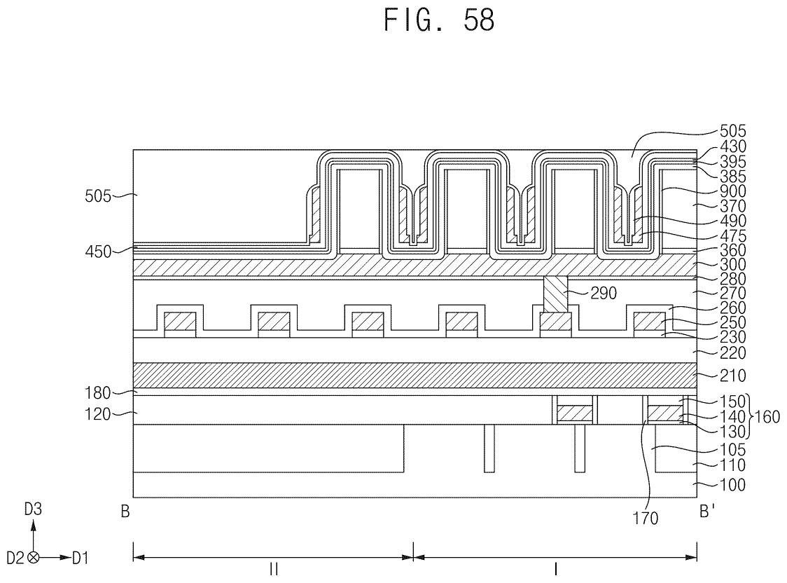

Referring to FIGS. 56 through 58, a planarization process, e.g., an etch back process, may be performed on the seventh insulating interlayer 500 until an upper surface of the first etch stop layer 490 is exposed to form a seventh insulating interlayer pattern 505.

In one or more example embodiments, the seventh insulating interlayer pattern 505 may extend in the second direction D2, and a plurality of seventh insulating interlayer patterns 505 may be spaced apart from each other in the first direction D1.

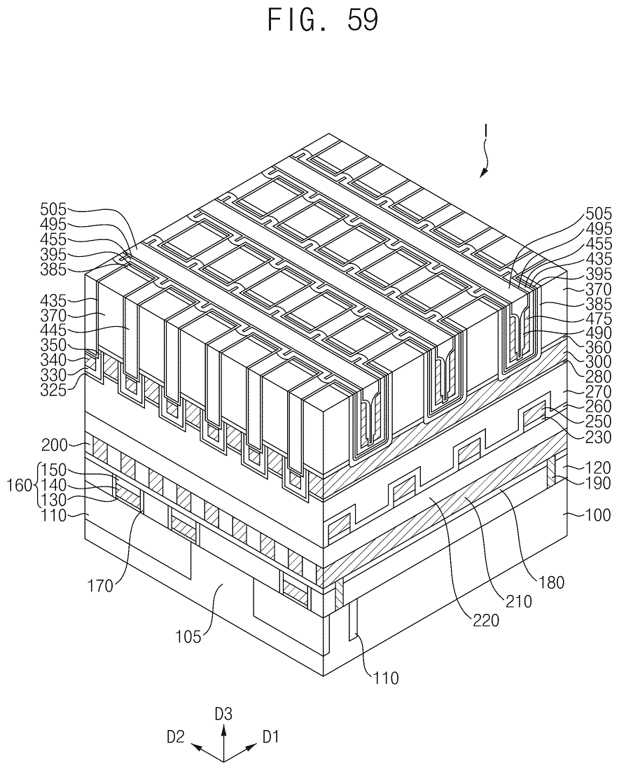

Referring to FIGS. 59 through 62, a planarization process may be performed on upper portions of the seventh insulating interlayer pattern 505, the first etch stop layer 490, the second gate insulation layer 450, the second capping layer 430, the first capping pattern 395, and the channel 385.

The planarization process may include a chemical mechanical polishing (CMP) process and/or an etch back process.

By the planarization process, the first etch stop layer 490, the second gate insulation layer 450, and the second capping layer 430 may be transformed into a first etch stop pattern 495, a second gate insulation pattern 455, and a second capping pattern 435, respectively. Each of the first etch stop pattern 495 and the second gate insulation pattern 455 may extend in the second direction D2. A plurality of first etch stop patterns 495 may be spaced apart from each other in the first direction D1, and a plurality of second gate insulation patterns 455 may be spaced apart from each other in the first direction D1. The second gate electrode 475 and the second gate insulation pattern 455 may collectively form a second gate structure.

The channel 385 extending in the first direction D1 may be divided into a plurality of parts spaced apart from each other in the first direction D1.

Referring to FIGS. 63 through 66, the seventh insulating interlayer pattern 505 and the first etch stop pattern 495 on the second region II of the substrate 100 may be partially removed to expose an upper surface of the second portion of the second gate electrode 475, and the second portion of the second gate electrode 475 may be removed to form a second opening.

Thus, in a plan view, the second gate electrode 475 having a ring shape may be divided into two second gate electrodes 475, each of which may extend in the second direction D2, opposite to each other in the first direction D1.

In one or more example embodiments, an annealing process such as a plasma treatment process using, e.g., oxygen plasma may be performed on the substrate 100 to reduce oxygen vacancies in the channel 385. The oxygen plasma may move to the channel 385 through the first mold 370 and the second gate electrode 475 exposed by the second opening to reduce the oxygen vacancies in the channel 385. The first mold 370 may include a low density material, e.g., a porous material, and thus, during the plasma treatment process, the oxygen plasma may move through the first mold.

The second opening may be filled with a ninth insulation pattern.

A second etch stop layer may be formed on the first mold 370, the first and second capping patterns 395 and 435, the second gate insulation pattern 455, the sixth and seventh insulating interlayer patterns 445 and 505, the first etch stop pattern 495, and the ninth insulation pattern, and a portion of the second etch stop layer on the second region II of the substrate 100 may be partially removed to form third to fifth openings exposing upper surfaces of the second gate electrode 475, the third wiring 300, and the fourth wiring 340, respectively, and fifth to seventh contact plugs 800, 810, and 815 may be formed in the third to fifth openings, respectively.

A portion of the second etch stop layer on the first region I of the substrate 100 may be removed, and thus a second etch stop pattern 515 may remain on the second region II of the substrate 100. An upper portion of the seventh insulating interlayer pattern 505 on the first region I of the substrate 100 may be partially removed by an etching process to form a fourth recess, and a fourth capping pattern 510 may be formed in the fourth recess. In one or more example embodiments, during the etching process, upper surfaces of the second gate electrode 475 and/or the first etch stop pattern 495 may be exposed, or upper portions of the second gate electrode 475 and/or the first etch stop pattern 495 may also be removed.

An upper portion of the channel 385 may be removed to form a fifth recess, and a first landing pad layer 530 may be formed on the first mold 370, the channel 385, the first and second capping patterns 395 and 435, the second gate insulation pattern 455, the sixth and seventh insulating interlayer patterns 445 and 505, the first and second etch stop patterns 495 and 515 and the fourth capping pattern 510 to fill the fifth recess.

In one or more example embodiments, a portion of the first landing pad layer 530 in the fifth recess may contact an upper surface of the channel 385.

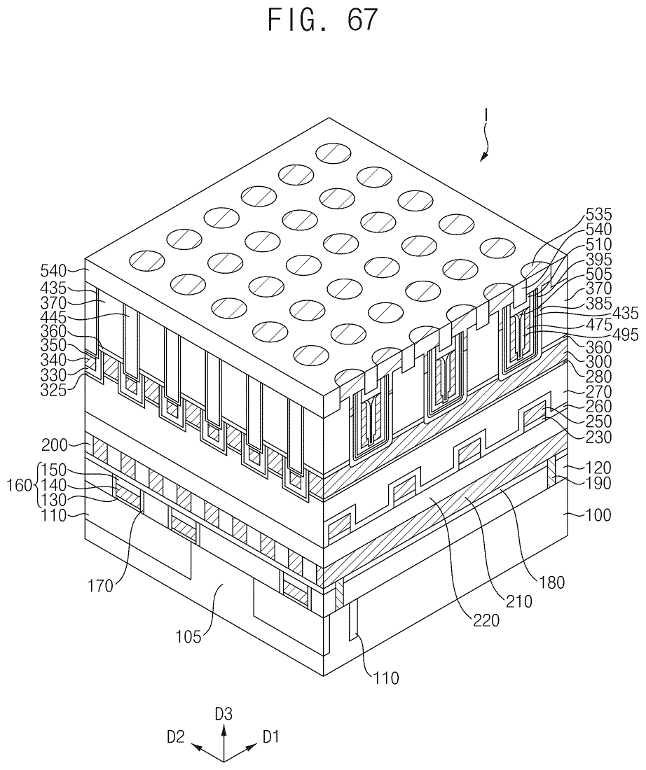

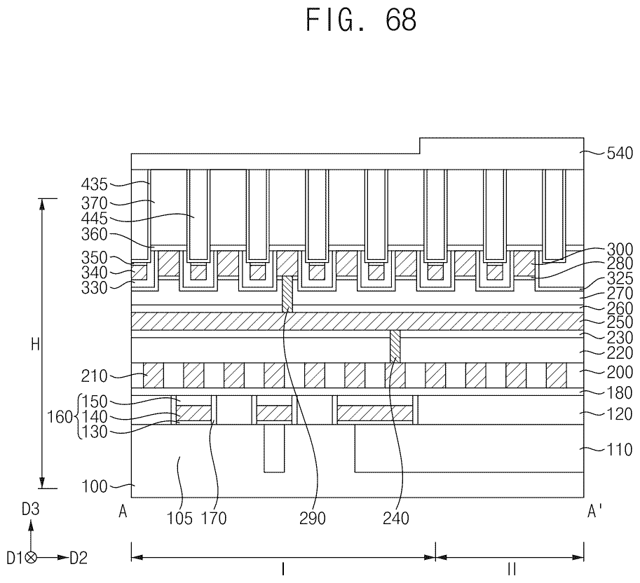

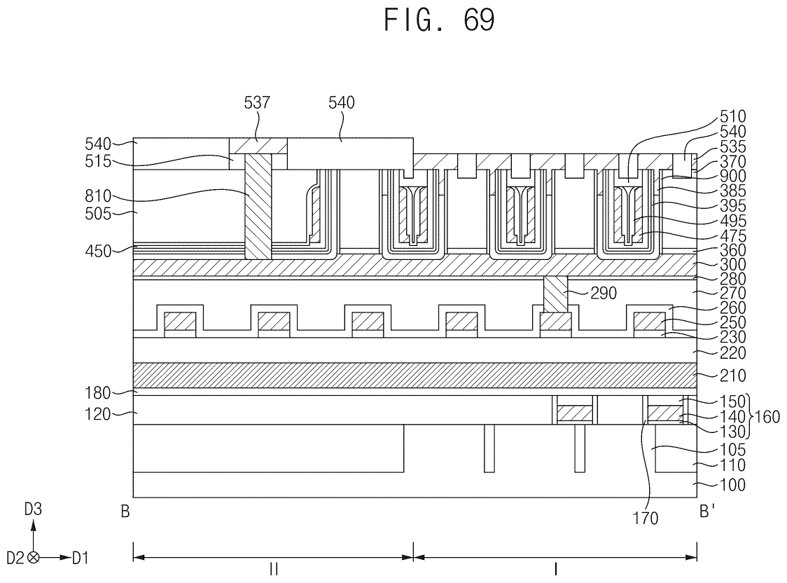

Referring to FIGS. 67 through 69, an etching process may be performed to form a sixth recess through the first landing pad layer 530, the second etch stop pattern 515, and upper portions of the first mold 370, the channel 385, the first and second capping patterns 395 and 435, the second gate insulation pattern 455, the sixth insulating interlayer pattern 445 and the fourth capping pattern 510, and an eighth insulating interlayer pattern 540 may be formed in the sixth recess.

By the etching process, the first landing pad layer 530 may be divided into a plurality of first landing pads 535 spaced apart from each other in each of the first and second directions D1 and D2 on the first region I of the substrate 100, and a plurality of second landing pads 537 spaced apart from each other in each of the first and second directions D1 and D2 on the second region II of the substrate 100.

In one or more example embodiments, each of the first and second landing pads 535 and 537 may have a shape of, e.g., a circle, an ellipse, a polygon, a polygon with rounded corners, etc., in a plan view. Each of the first landing pads 535 may contact the upper surface of the channel 385 through a lower portion of the first landing pad 535 in the fifth recess, and the second landing pads 537 may contact upper surfaces of the fifth to seventh contact plugs 800, 810 and 815, respectively.

The second etch stop pattern 515 on the second region II of the substrate 100 may remain only under each of the fifth to seventh contact plugs 800, 810 and 815.

Referring back to FIGS. 1 through 4, a third etch stop layer 550 may be formed on the eighth insulating interlayer pattern 540 and the first and second landing pads 535 and 537, a support layer 560 and capacitors 570 may be formed on the first region I of the substrate 100, and eighth contact plugs 575 may be formed on the second region II of the substrate 100.

The capacitors 570 may contact upper surfaces of the first landing pads 535, respectively, and the eighth contact plugs 575 may contact upper surfaces of the second landing pads 537, respectively.

A plasma treatment process using oxygen plasma may be further performed on the substrate 100, so that the oxygen vacancies in the channel 385 may be reduced. The oxygen plasma may move to the channel 385 through the first mold 370, the eighth contact plug 575, the second landing pad 537, the third contact plug 800 and the second gate electrode 475 so that the oxygen vacancies in the channel 385 may be reduced. The first mold 370 may include the low density material such as the porous material, and thus the oxygen plasma may move through the first mold 370 during the plasma treatment process.

The semiconductor device may be manufactured by the above processes.

As illustrated above, the oxygen vacancies in the channel 385 may be reduced by the oxygen plasma treatment process, and during the oxygen plasma treatment process, the first mold 370 serving as a path for the oxygen plasma may include the porous material instead of, e.g., silicon oxide, so that the movement of the oxygen plasma may be enhanced and that the reduction of the oxygen vacancies may be improved.

The foregoing is illustrative of one or more example embodiments and is not to be construed as limiting thereof. Although one or more example embodiments have been described, those skilled in the art will readily appreciate that many modifications are possible in the embodiments disclosed herein without materially departing from the teachings and advantages of the present disclosure. Accordingly, all such modifications are intended to be included within the scope of the present disclosure as defined in the claims. In the claims, means-plus-function clauses are intended to cover the structures described herein as performing the recited function and not only structural equivalents but also equivalent structures. Therefore, it is to be understood that the foregoing is illustrative of one or more example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device comprising:
a bit line on a substrate, the bit line extending in a first direction substantially parallel to an upper surface of the substrate;
a mold on the bit line, the mold comprising a porous insulating material;
a channel on a sidewall of the mold, wherein the channel is connected to the bit line;
an interface pattern between and contacting the channel and the mold;
a gate insulation pattern on a sidewall of the channel;
a gate electrode on a sidewall of the gate insulation pattern; and
a capacitor on and connected to the channel.

2. The semiconductor device of claim 1, wherein the mold comprises silicon oxide doped with carbon (SiOCH) or silicon carbonitride (SiCN).

3. The semiconductor device of claim 2, wherein the interface pattern comprises silicon oxide.

4. The semiconductor device of claim 1, further comprising a plurality of molds comprising the mold,
wherein the plurality of molds are spaced apart from each other in the first direction,
wherein the channel is between molds from among the plurality of molds that neighbor one another in the first direction, and
wherein a cross-section of the channel in the first direction has a cup shape.

5. The semiconductor device of claim 1, further comprising an insulation pattern between an upper surface of the bit line and a lower surface of the mold,
wherein the interface pattern contacts a sidewall of the mold and a sidewall of the insulation pattern.

6. The semiconductor device of claim 1, further comprising a landing pad between the channel and the capacitor,
wherein the landing pad comprises a lower portion and an upper portion stacked in a vertical direction substantially perpendicular to the upper surface of the substrate, and
wherein a sidewall of the lower portion of the landing pad contacts the interface pattern.

7. The semiconductor device of claim 1, wherein an uppermost surface of the gate electrode is lower than an uppermost surface of the gate insulation pattern.

8. The semiconductor device according to claim 1, further comprising a bit line shield on the substrate, the bit line shield being spaced apart from the bit line in a second direction substantially parallel to the upper surface of the substrate and crossing the first direction.

9. The semiconductor device of claim 8, wherein the bit line and the bit line shield are alternately and repeatedly disposed in the second direction.

10. The semiconductor device of claim 1,
wherein the gate insulation pattern extends in a second direction substantially parallel to the upper surface of the substrate and crossing the first direction, and
wherein a cross-section of the gate insulation pattern in the first direction has a cup shape.

11. The semiconductor device of claim 10, further comprising a plurality of gate insulation patterns spaced apart from each other in the first direction and a plurality of gate electrodes spaced apart from each other in the first direction, the gate insulation pattern being one of the plurality of gate insulation patterns and the gate electrode being one of the plurality of gate electrodes,
wherein each of the plurality of gate electrodes extends in the second direction.

12. A semiconductor device comprising:
a bit line on a substrate, the bit line extending in a first direction substantially parallel to an upper surface of the substrate;
a mold on the bit line, the mold comprising a porous insulating material;
interface patterns on opposite sidewalls of the mold, respectively, the interface patterns comprising silicon oxide;
a channel on a sidewall of each of the interface patterns, the channel being connected to the bit line;
a gate insulation pattern on a sidewall of the channel;
a gate electrode on a sidewall of the gate insulation pattern; and
a capacitor on and connected to the channel.

13. The semiconductor device of claim 12, wherein the mold comprises silicon oxide doped with carbon (SiOCH) or silicon carbonitride (SiCN).

14. The semiconductor device of claim 12, further comprising a plurality of molds comprising the mold,
wherein the plurality of molds are spaced apart from each other in the first direction,
wherein the channel is between molds from among the plurality of molds that neighbor one another in the first direction, and
wherein a cross-section of the channel in the first direction has a cup shape.

15. The semiconductor device claim 12, further comprising an insulation pattern between an upper surface of the bit line and a lower surface of the mold,
wherein each of the interface patterns contacts opposite sidewalls of the mold and opposite sidewalls of the insulation pattern.

16. The semiconductor device of claim 12, further comprising a landing pad between the channel and the capacitor,
wherein the landing pad comprises a lower portion and an upper portion stacked in a vertical direction substantially perpendicular to the upper surface of the substrate, and
wherein a sidewall of the lower portion of the landing pad contacts each of the interface patterns.

17. A semiconductor device comprising:
bit lines on a substrate, each of the bit lines extending in a first direction substantially parallel to an upper surface of the substrate, wherein the bit lines are spaced apart from each other in a second direction substantially parallel to the upper surface of the substrate and crossing the first direction;
bit line shields between the bit lines and extending in the first direction;
molds spaced apart from each other in the first direction on each of the bit lines, wherein the molds comprise a porous insulating material;
channels each connected to a corresponding one of the bit lines, wherein each of the channels is between molds that neighbor one another in the first direction;
an interface pattern between and contacting each of the channels and one of the molds adjacent to each of the channels;
a gate insulation pattern on a sidewall of each of the channels;
a gate electrode on a sidewall of the gate insulation pattern;
landing pads on the channels, respectively; and
capacitors on and connected to the channels, respectively.

18. The semiconductor device of claim 17, wherein each of the molds comprises silicon oxide doped with carbon (SiOCH) or silicon carbonitride (SiCN).

19. The semiconductor device of claim 17, wherein the interface pattern comprises silicon oxide.

20. The semiconductor device of claim 17, further comprising an insulation pattern between a lower surface of each of the molds and an upper surface of the corresponding bit lines,
wherein the interface pattern contacts sidewalls of the molds and sidewalls of the insulation pattern.
